(19) United States
(12) Patent Application Publication
(10) Pub. No.: US 2025/0194051 A1
(43) Pub. Date: Jun. 12, 2025

(54) MODULAR AND SCALABLE QUANUTM COMPUTER WITH TRAPEZOIDAL UNIT CELLS

(71) Applicant: International Business Machines Corporation, Armonk, NY (US)

(72) Inventor: Shawn Anthony Hall, Pleasantville, NY (US)

(21) Appl. No.: 18/533,588

(22) Filed: Dec. 8, 2023

(51) Int. Cl. H05K 7/20; G06N 10/40

(52) U.S. Cl. CPC H05K 7/20372; G06N 10/40

(57) ABSTRACT

Systems and techniques that facilitate scalable cryostats and cryogenic systems are provided. In an embodiment, a cryogenic system can comprise a plurality of unit cells joined together, wherein each unit cell comprises: a trapezoidal-shaped frame, wherein frames from adjacent unit cells are connected in a vacuum-tight manner to form a continuous, global vacuum enclosure, and wherein the unit cells are capable of being horizontally removed from or inserted into the plurality of joined unit cells. Furthermore, each unit cell can comprise at least one temperature shell, wherein temperature shells from adjacent unit cells are connected to form a continuous, global temperature shell. Moreover, each unit cell can comprise at least one cryogenic payload located within the at least one temperature shell, that is cooled by at least one retrofitted version of a standard dilution refrigerator.

### BACKGROUND

The subject disclosure relates to cryostats, and more specifically modular cryostats to enable scalable quantum computers.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices and/or method that facilitate modular cryostats that facilitate scalable quantum computers are described.

According to an embodiment, a cryogenic system can comprise a plurality of trapezoidal shaped unit cells joined together, wherein each unit cell comprises: a frame, wherein frames from adjacent trapezoidal unit cells are connected in a vacuum-tight manner at abutting surfaces of the adjacent trapezoidal unit cells. An advantage of such a system is that the plurality of trapezoidal unit cells allows for greater scalability of the cryogenic system, as more unit cells can be joined together to create a larger cryogenic system, as opposed to having to build and an entirely new larger cryostat. A further advantage of the trapezoidal unit cells is that any unit cell may be replaced by horizontal extraction and insertion processes that do not require undue ceiling height.

According to another embodiment, a cryogenic system can comprise a plurality of unit cells joined together, wherein each unit cell comprises: a frame; a plurality of nested temperature shells at a plurality of temperature levels; at least one retrofitted version of a standard dilution refrigerator; and at least one cryogenic payload located within at least one of the different temperature levels, that is cooled by the at least one retrofitted version of a standard dilution refrigerator; wherein frames from adjacent unit cells are connected in a vacuum-tight manner at abutting surfaces of the adjacent unit cells, and at each temperature level, temperature shells from adjacent unit cells are connected to form a continuous, global temperature shell. An advantage of such a system is that the plurality of unit cells allows for greater scalability of the cryogenic system, as more unit cells can be joined together to create a larger cryogenic system, as opposed to having to build and an entirely new, larger cryostat. Another advantage of such a system is that refrigerator design is decoupled from application-specific mechanical requirements, such that the mechanical needs of an evolving application are not hampered by mechanical constraints that would otherwise be imposed by the refrigerator.

According to another embodiment, a cryogenic system can comprise a plurality of trapezoidal unit cells joined together, wherein each unit cell comprises: a frame assembly comprising at least one door that forms a vacuum-tight seal when closed; at least one temperature shell suspended from a set of flanges; at least one retrofitted version of a standard dilution refrigerator; and at least one cryogenic payload located within the at least one temperature shell, wherein, that is cooled by the at least one retrofitted version of a standard dilution refrigerator, frames from adjacent trapezoidal unit cells are connected in a vacuum-tight manner at abutting surfaces of the adjacent trapezoidal unit cells, and temperature shells from the adjacent trapezoidal unit cells are connected to form a continuous, global temperature shell. An advantage of such a system is that the plurality of unit cells allows for greater scalability of the cryogenic system, as more unit cells can be joined together to create a larger cryogenic system, as opposed to having to build and an entirely new, larger cryostat. A further advantage of the trapezoidal unit cells is that any unit cell may be replaced by horizontal extraction and insertion processes that do not require undue ceiling height. Another advantage of such a system is that refrigerator design is decoupled from application-specific mechanical requirements, such that the mechanical needs of an evolving application are not hampered by mechanical constraints that would otherwise be imposed by the refrigerator.

### DESCRIPTION OF THE DRAWINGS

FIG. 1 illustrates a cutaway view of an existing dilution refrigerator.

FIG. 2 illustrates a cutaway view of a juxtaposition of two existing dilution refrigerators.

FIG. 3 illustrates an array of trapezoidal unit cells in accordance with one or more embodiments described herein.

FIG. 4 illustrates a top orthographic view of an array of trapezoidal unit cells in accordance with one or more embodiments described herein.

FIG. 5 illustrates a cutaway view of an array of trapezoidal unit cells in accordance with one or more embodiments described herein.

FIG. 6 illustrates a cutaway view of an array of trapezoidal unit cells in accordance with one or more embodiments described herein.

FIG. 7 illustrates an artificially exploded view of trapezoidal unit cells with closed doors in accordance with one or more embodiments described herein.

FIG. 8 illustrates an artificially exploded view of trapezoidal unit cells with open doors in accordance with one or more embodiments described herein.

FIG. 9 illustrates an artificially exploded view of trapezoidal unit cells without end shields or bridge shields in accordance with one or more embodiments described herein.

FIG. 10 illustrates an artificially exploded view of trapezoidal unit cells without default shields in accordance with one or more embodiments described herein.

FIG. 11 illustrates a populated trapezoidal unit cell in accordance with one or more embodiments described herein.

FIG. 12 illustrates frame assembly of a populated trapezoidal unit cell in accordance with one or more embodiments described herein.

FIG. 13 illustrates a right-front view of frame assembly of a trapezoidal unit cell in accordance with one or more embodiments described herein.

FIGS. 14A and 14B illustrate a left-front and rear view of frame assembly of a trapezoidal unit cell in accordance with one or more embodiments described herein.

FIG. 15 illustrates a top view of frame assembly of a trapezoidal unit cell in accordance with one or more embodiments described herein.

FIG. 16 illustrates a first perspective view of insert assembly in accordance with one or more embodiments described herein.

FIG. 17 illustrates a second perspective view of insert assembly in accordance with one or more embodiments described herein.

FIG. 18 illustrates an orthographic view of insert assembly in accordance with one or more embodiments described herein.

FIG. 19 illustrates an orthographic view of insert assembly in accordance with one or more embodiments described herein.

FIG. 20 illustrates an exploded view of a thermal shell in accordance with one or more embodiments described herein.

FIG. 21 illustrates a thermal shell after a first assembly step in accordance with one or more embodiments described herein.

FIG. 22 illustrates a thermal shell after a second assembly step in accordance with one or more embodiments described herein.

FIG. 23 illustrates a thermal shell after a third assembly step in accordance with one or more embodiments described herein.

FIG. 24 illustrates a fully assembled thermal shell in accordance with one or more embodiments described herein.

FIG. 25 illustrates affixed shields to flange in a thermal shell in accordance with one or more embodiments described herein.

FIG. 26 illustrates affixed opposing shields in a thermal shell in accordance with one or more embodiments described herein.

FIG. 27 illustrates overlapping of center shields and bridge shields on lateral shields in a thermal shell in accordance with one or more embodiments described herein.

FIG. 28 illustrates affixed center shields and bridge shields to lateral shields in a thermal shell in accordance with one or more embodiments described herein.

FIG. 29 illustrates affixed opposing side-bridge shields in a thermal shell in accordance with one or more embodiments described herein.

FIG. 30 illustrates overlapping of top-bridge shields on flanges and side-bridge shields in a thermal shell in accordance with one or more embodiments described herein.

FIG. 31 illustrates refrigerator insertion for retrofitting of an off-the-shelf dilution refrigerator in accordance with one or more embodiments described herein.

FIG. 32 illustrates refrigerator insertion for retrofitting of an off-the-shelf dilution refrigerator in accordance with one or more embodiments described herein.

FIG. 33 illustrates affixed custom thermal flanges for retrofitting of an off-the-shelf dilution refrigerator in accordance with one or more embodiments described herein.

FIG. 34 illustrates affixed custom thermal flanges retrofitting of an off-the-shelf dilution refrigerator in accordance with one or more embodiments described herein.

FIG. 35 illustrates affixed custom thermal flanges retrofitting of an off-the-shelf dilution refrigerator in accordance with one or more embodiments described herein.

FIG. 36 illustrates affixed custom thermal flanges retrofitting of an off-the-shelf dilution refrigerator in accordance with one or more embodiments described herein.

FIG. 37 illustrates affixed custom thermal flanges retrofitting of an off-the-shelf dilution refrigerator in accordance with one or more embodiments described herein.

FIG. 38 illustrates a first field-replaceable unit strategy in accordance with one or more embodiments described herein.

FIG. 39 illustrates a second field-replaceable unit strategy in accordance with one or more embodiments described herein.

FIG. 40 illustrates a third field-replaceable unit strategy with horizontal extraction of a unit cell in accordance with one or more embodiments described herein.

FIG. 41 illustrates a first position of the extraction process of a unit cell for replacement in accordance with one or more embodiments described herein.

FIG. 42 illustrates a second position of the extraction process of a unit cell for replacement in accordance with one or more embodiments described herein.

FIG. 43 illustrates a third position of the extraction process of a unit cell for replacement for replacement in accordance with one or more embodiments described herein.

FIG. 44 illustrates a fourth position of the extraction process of a unit cell for replacement in accordance with one or more embodiments described herein.

FIG. 45 illustrates a top view of the first position of the extraction process in accordance with one or more embodiments described herein.

FIG. 46 illustrates a rear view of the first position of the extraction process in accordance with one or more embodiments described herein.

FIG. 47 illustrates a front view of the first position of the extraction process in accordance with one or more embodiments described herein.

FIG. 48 illustrates fully compressed frame O-rings during extraction of a unit cell in accordance with one or more embodiments described herein.

FIG. 49 illustrates a top view of the transition from a fully compressed frame O-ring to an uncompressed frame O-ring in accordance with one or more embodiments described herein.

FIG. 50 illustrates uncompressed frame O-rings during extraction of a unit cell in accordance with one or more embodiments described herein.

FIG. 51 illustrates uncompressed frame O-rings during extraction of a unit cell in accordance with one or more embodiments described herein.

FIG. 52 illustrates insertion of a unit cell in accordance with one or more embodiments described herein.

FIG. 53 illustrates insertion of a unit cell in accordance with one or more embodiments described herein.

FIG. 54 illustrates insertion of a unit cell in accordance with one or more embodiments described herein.

FIG. 55 illustrates insertion of a unit cell in accordance with one or more embodiments described herein.

FIG. 56 illustrates a transparent view of insertion of a unit cell in accordance with one or more embodiments described herein.

FIG. 57 illustrates a top-view, free-body diagram of forces on a cell during O-ring-compression during the insertion process in accordance with one or more embodiments described herein.

FIG. 58 illustrates x-directed forces on a unit cell in accordance with one or more embodiments described herein.

FIG. 59 illustrates an array of trapezoidal unit cells in accordance with one or more embodiments described herein.

FIG. 60 illustrates an array of rectangular unit cells in accordance with one or more embodiments described herein.

FIG. 61 illustrates an array of unpopulated unit cells in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

To solve computational problems unachievable by classical computers, a quantum computer comprises a large number N of physical qubits. Historically, quantum computers comprising superconducting qubits have been small enough that all N qubits and supporting equipment fit in a single existing cryostat. However, because N continually grows as quantum technology progresses, the number of qubits is now so large that a single monolithic refrigerator can no longer accommodate all of them. As N continues to grow, building ever-larger dilution refrigerators utilizing existing designs grows increasingly expensive, and leads to hardware sizes that are ultimately untenable, cumbersome, and unmanageable. Accordingly, when N exceeds the number of qubits that can be packaged together, a number that depends on engineering limits of qubit-supporting infrastructure (e.g., chips, circuit-boards, connectors, cabling, and cooling equipment), then the N qubits are divided into a plurality of groups called payloads. Yet, for a quantum computer to be effective, payloads must be able to send electromagnetic signals to their neighbors over quantum-link cables that are as short as possible, and which remain superconducting over their entire length to minimize loss.

However, it is difficult to build such a multi-payload quantum computer simply by juxtaposing a plurality of conventional dilution refrigerators, each containing a payload, and connecting quantum-link cables between them, because to travel between such refrigerators, a portion of each cable would have to be at room temperature and thus would be far too lossy, because no superconducting materials are currently known to exist at ambient temperature and pressure. Moreover, cables between existing refrigerators would be excessively long, which is also a source of loss.

In one or more embodiments described herein, systems, devices and/or method that facilitate modular cryostats that facilitate scalable quantum computers are described that address the above-described problems with existing dilution refrigerators and cryostats. In one or more embodiments described herein, a cryogenic system can comprise a plurality of unit cells joined together, wherein each unit cell comprises: a frame; and at least one temperature shell; wherein frames from adjacent unit cells are connected in a vacuum-tight manner to form a continuous, global vacuum enclosure, and temperature shells from adjacent unit cells are connected to form a continuous, global temperature shell. Accordingly, the unit cell structure of the cryogenic system enables scalability of the system as more unit cells can be added or removed from the system to enable scalability to the desired size of cryostat. Furthermore, in one or more embodiments described herein, the cryogenic system can further comprise at each end of the plurality of unit cells an end frame, such that the plurality of frames and end frames together form a vacuum-tight vessel; and an end cap for the global temperature shell at each end of the plurality of unit cells, such that the global temperature shell and end caps form a substantially closed, radiation-resistant thermal enclosure. As used herein the term “thermal shell” can be interchangeable with temperature shell.

For example, in one or more embodiments herein, a modular, scalable quantum computer can comprise an array of n+4 unit cells arrayed along an imaginary x axis of an imaginary Cartesian xyz coordinate system where +z is vertical upward, and where n is a integer greater than or equal to zero. Denoting various cell types by letters, the array can comprise cells {A B D E}, or {A B C₁ C₂ D E}, or {A B C₁ C₂ C₃ D E}, or more generally {A B C₁ C₂ . . . Cₙ D E}, where C₁, C₂, . . . , Cₙ are instances of C and n of the cells are type C. In this nomenclature, A is an unpopulated, left-end unit cell; B is a populated unit cell with left-end thermal shields; C is a default, populated unit cell; D is a populated unit cell with right-end thermal shields, and E is an unpopulated, right-end unit cell. Each unit cell, whether type A, B, C, D, or E, can comprise a frame assembly that can comprise a frame, two hinged, vacuum-sealed door assemblies abutting the +y and −y faces of the frame, and a skylight assembly abutting the +z face of the frame. In one or more “rectangular embodiments” in which frames have a rectangular planform shape, the frame assembly can be identical for all cell types. In one or more “trapezoidal embodiments” in which frames have a trapezoidal planform shape, the frame assembly can be of two types, denoted L and R respectively, that alternate along the array. For example, in the array {A B C₁ C₂ C₃ D E}, cells A, C1, C3, and E can comprise frame-assembly type L, while cells B, C2, and D can comprise frame-assembly type R. The frames of adjacent cells can be abutted in a vacuum-tight manner. Cell A can comprise a left-end-wall assembly that is affixed to the −x face of A's frame in a vacuum-tight manner; likewise, cell E can comprise a right-end-wall assembly that is affixed to the +x face of E's frame in a vacuum-tight manner. Consequently, the array of frame assemblies and end-wall assemblies together can form a vacuum-tight shell. Cell types B, C, and D each can comprise a dilution-refrigerator assembly that can be affixed to the skylight assembly, such that various arrangements of refrigeration equipment and other infrastructure can be accommodated by re-designing the skylight assembly only, but without re-designing the frame and door assemblies. Cell types B, C, and D can each further comprise a quantum payload assembly comprising NQ qubits as well as the electronic infrastructure necessary to support them, the payload assembly being affixed to a base-temperature flange of the dilution-refrigerator.

The dilution-refrigerator assembly in each cell B, C, D can comprise an array of thermal side-shields on its +y and −y faces. Additionally, the dilution-refrigerator assembly in cell B can comprise an array of left-end thermal shields on its −x face, and the dilution-refrigerator assembly in cell D can comprise an array of right-end thermal shields on its +x face. Thus, the entire array of refrigerators can be surrounded by a continuous set of thermal shields on all sides, thereby providing one large, evacuated, thermally shielded space in which all the payloads of cells {B C₁ C₂ . . . Cₙ D} reside, with no barriers between payloads. Consequently, superconducting quantum-link cables (and other equipment if desired) can be connected between payloads without encountering barriers and without leaving the confines of the innermost, base-temperature shell of the aggregated dilution refrigerators, thereby ensuring that the quantum-link cables remain superconducting. Furthermore, the link cables can be relatively short, thereby both decreasing material and production costs of the link cables, as well as improving performance.

Additionally, because it is modular, the unit cell can be designed to be physically manageable; for example, one of its dimensions can be relatively small so that a unit cell can fit through typical doorways. Moreover, in one or more embodiments, the unit cell can be designed to be flexible, such that various types of refrigeration equipment, payload, and signal-delivery can be accommodated without re-designing any of the frame assembly except the skylight assembly. In addition, the modularity of the cells further enables easier maintenance and repairs, because the dilution-refrigeration unit and payload of any cell can, by virtue of the skylight assembly, be withdrawn vertically from the frame for servicing or replacement. Moreover, for installations in which such vertical withdrawal of equipment through the skylight is impossible due to restricted ceiling height, the trapezoidal embodiments provide an alternative servicing means; namely, horizontal withdrawal of an entire defective unit cell, and horizontal replacement thereof with a non-defective unit cell, thereby to avoid the need for a high ceiling in the location where the quantum computer is installed. Modularity of the cells also reduces design effort and expense required to scale the quantum computer to accommodate a growing number N of qubits, because it suffices merely to add more unit cells C to the array.

Variations of one or more embodiments are also envisioned. For example, if the left-end thermal shields and right-end thermal shields do not protrude beyond the confines of cells B and D, respectively, then cells A and E can be omitted, leaving {B C₁ C₂ . . . Cₙ D}, in which case the left-end-wall assembly can be affixed to the −x face of cell B, and the right-end-wall assembly can be affixed to the +x face of cell D. As another example, if the aforesaid flexibility in the arrangement of cooling equipment and payload-wiring infrastructure is not needed, and the aforesaid option to withdraw the dilution-refrigeration and payload from the frame for servicing and replacement is not needed, then the skylight assembly can be eliminated in favor of connecting refrigeration equipment and other infrastructure directly to the +z surface of the frame.

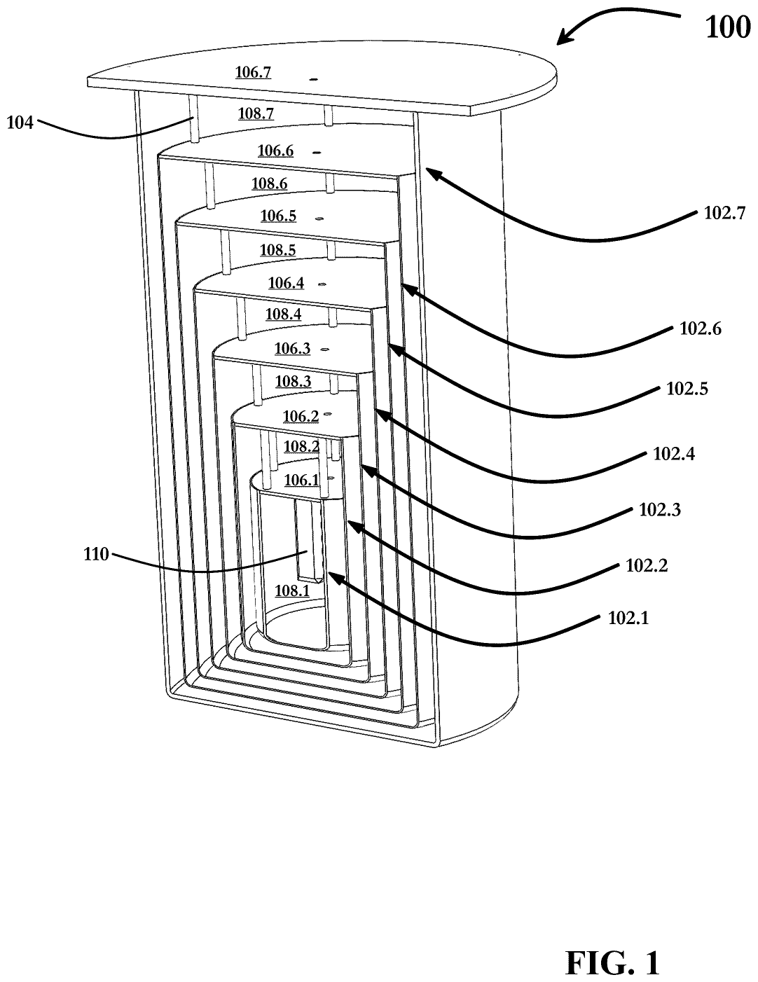

As illustrated in FIG. 1, an existing dilution refrigerator 100 comprises a plurality of nested shells 102 (e.g., 102.1, 102.2, . . . , 102.7) connected to each other with standoffs 104, where each shell comprises a flange 106 and a can 108. Standoffs 104 must be long enough to prevent undue heat conduction between shells and to accommodate refrigeration equipment not shown. By means of the refrigeration equipment, the various shells 102 are held at different temperatures: outermost shell 102.7 is held at a room temperature such as T₇=300K; innermost shell 102.1 is held at a base temperature such as T₁=20 mK; and intervening shells 102.2, . . . , 102.6 are held at intermediate temperatures T₂, . . . , T₆, respectively, such as 100 mK, 800 mK, 4K, 10K, and 50K, respectively. Inner cans 108.1, 108.2, . . . , 108.6 are radiation shields that prevent higher-temperature radiation from falling on lower-temperature shells and thereby overwhelming the refrigeration equipment with excessive heat load. Outermost can 108.7 is a vacuum enclosure, because cryogenically cooled equipment must be in vacuum to avoid frozen water and air. To function properly, a payload 110 comprising superconducting qubits must be held at temperature T₁ and must avoid radiation from higher temperature; consequently, payload 110 must exist inside the innermost shell 102.1, as shown. To gain access to payload 110 for service, all cans 108 are removed one by one, starting with the vacuum can 108.7. Likewise, after servicing, prior to restarting the quantum computer 100, all cans 108 are replaced, starting with innermost can 108.1.

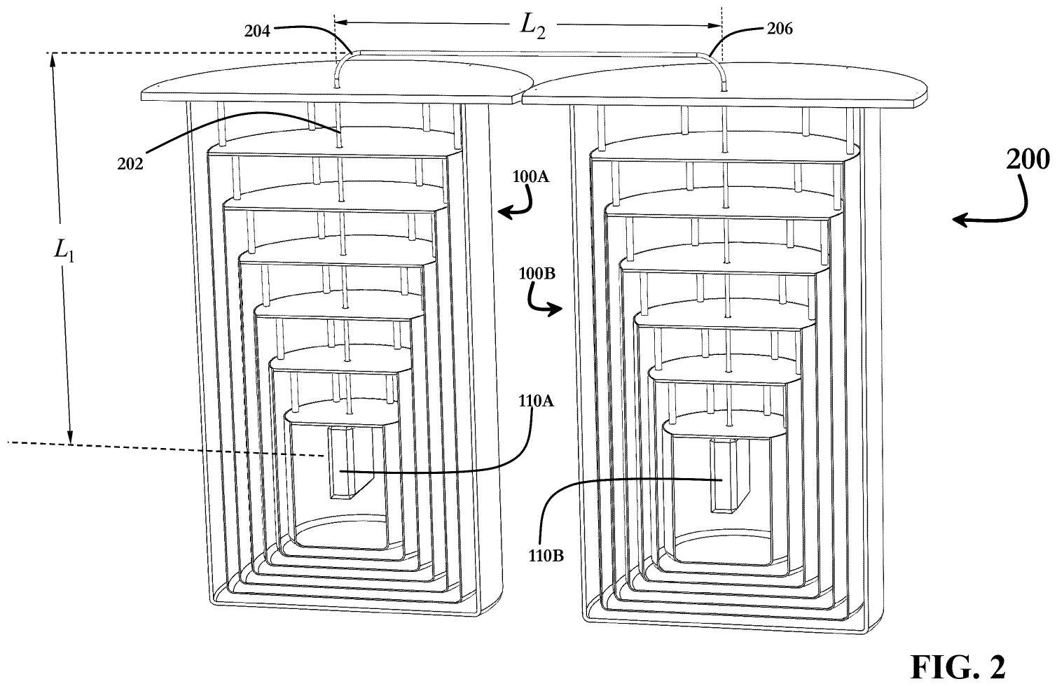

Referring to FIG. 2, consider a juxtaposition 200 of two existing dilution refrigerators 100A and 100B that house quantum payloads 110A and 110B, respectively. Because of the topology of the conventional refrigerators, a quantum-link cable 202 cannot travel directly between payloads 110A and 110B because cans 108 are impenetrable barriers that must also be, as explained above, removable, which precludes the notion of passing cables through small holes in the cans. Consequently, cable 202 comprises three portions as shown: a first portion of Manhattan length L₁ that extends from payload 110A to corner 204, a second portion of Manhattan length L₂ that extends from corner 204 to corner 206, and a third portion of Manhattan length L₁ that extends from corner 206 to payload 110B. Unfortunately, over a considerable portion of cable 202's length, its conducting elements do not superconduct despite being composed of superconducting material, because said portion is at a temperature above the superconducting-transition temperature of known materials suitable for cables. In particular, the second portion is at room temperature, where no known materials superconduct. Thus, cable 202 is unsuitable to carry quantum signals from payload to payload, because the loss of quantum information is excessive. Moreover, cable 202 is quite long, having length L=2L₁+L₂, which further incurs loss. For example, in an existing dilution refrigerator, L₁≥1100 mm and L₂≥865 mm, whence L≥3,065 mm, which is far longer than desired for a low-loss, quantum-link cable, thereby degrading performance.

Consequently, to enable quantum computers in which N is so large that qubits must be grouped into physically separated payloads that are connected by quantum-link cables, it is desirable to repackage conventional dilution refrigerators in a manner that eliminates the problems just described. Specifically, because operation at non-superconducting temperatures and increases in cable length increase loss, it is desirable to eliminate barriers between payloads so that payload-to-payload quantum-link cables can remain superconducting over their entire length, and so their length can be relatively short (e.g., approximately one meter in length). It is also desirable for the repackaged refrigerators to be physically manageable to facilitate moving the equipment, navigating it through doorways, and installing it, manageability that is lacking in large conventional refrigerators, because they are typically large in all three dimensions. It should also be appreciated that repackaging existing refrigerators as described herein, as opposed to designing and building new refrigerators from scratch, is advantageous for two reasons: first, development cost and time are saved; second, capital cost is saved because already-purchased refrigerators can be recycled in the modular, scalable equipment described herein.

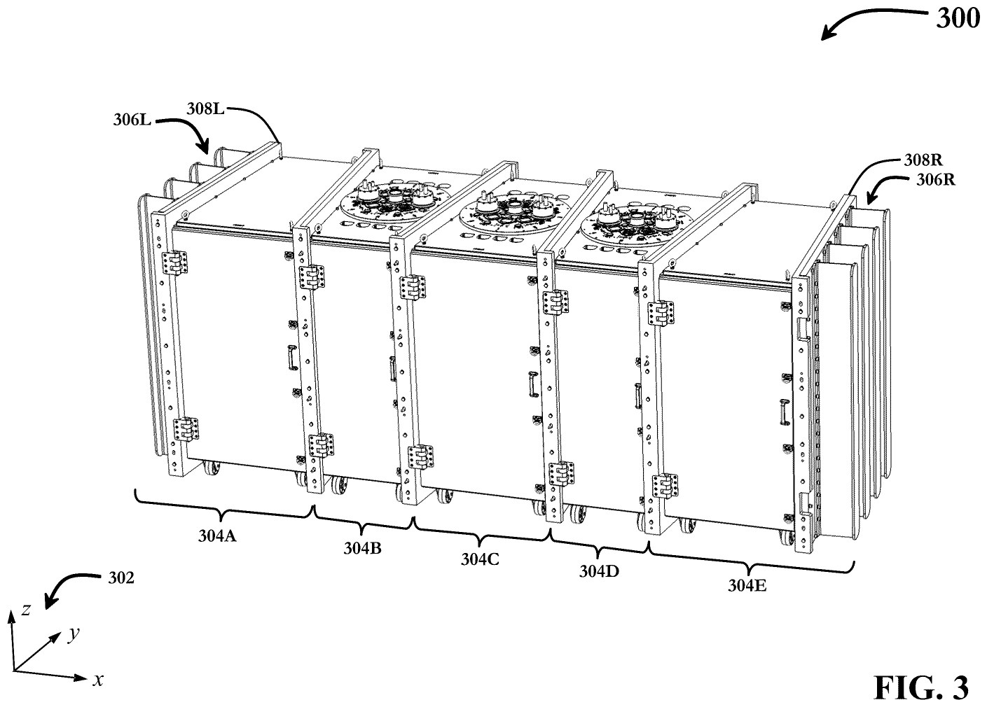

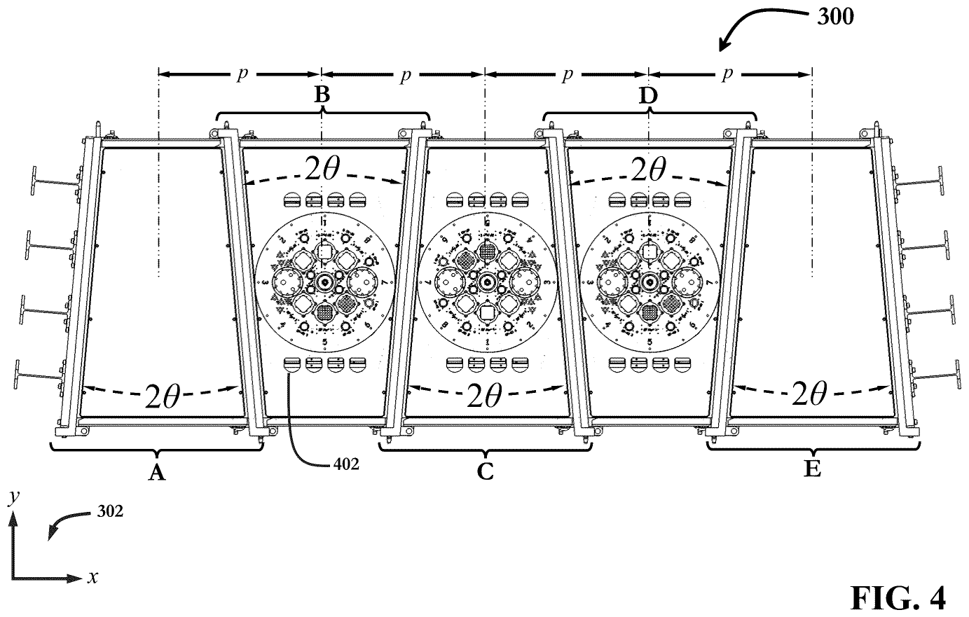

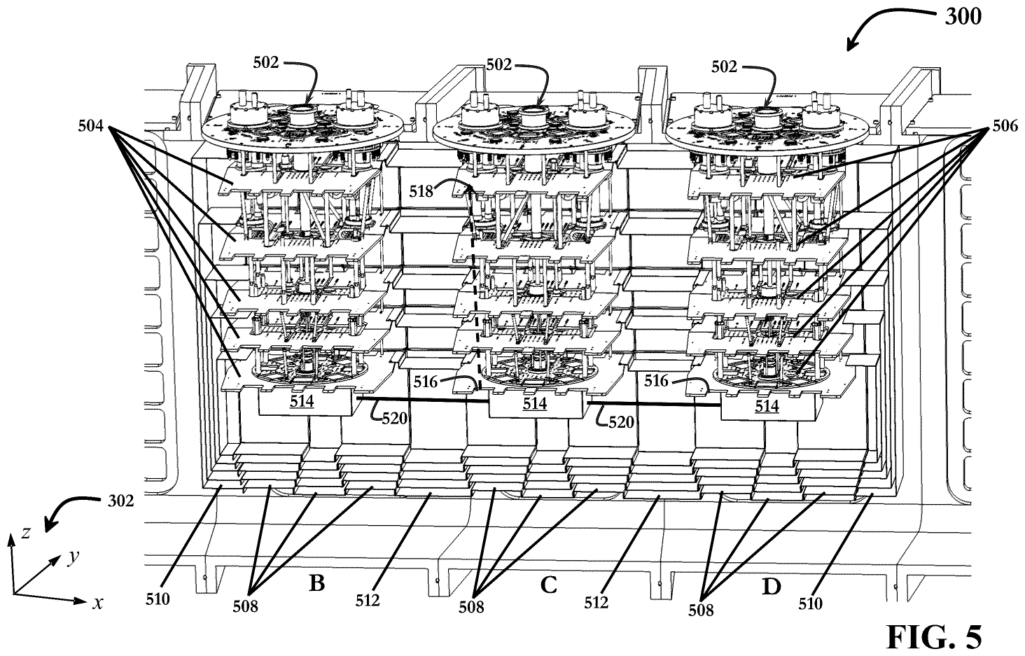

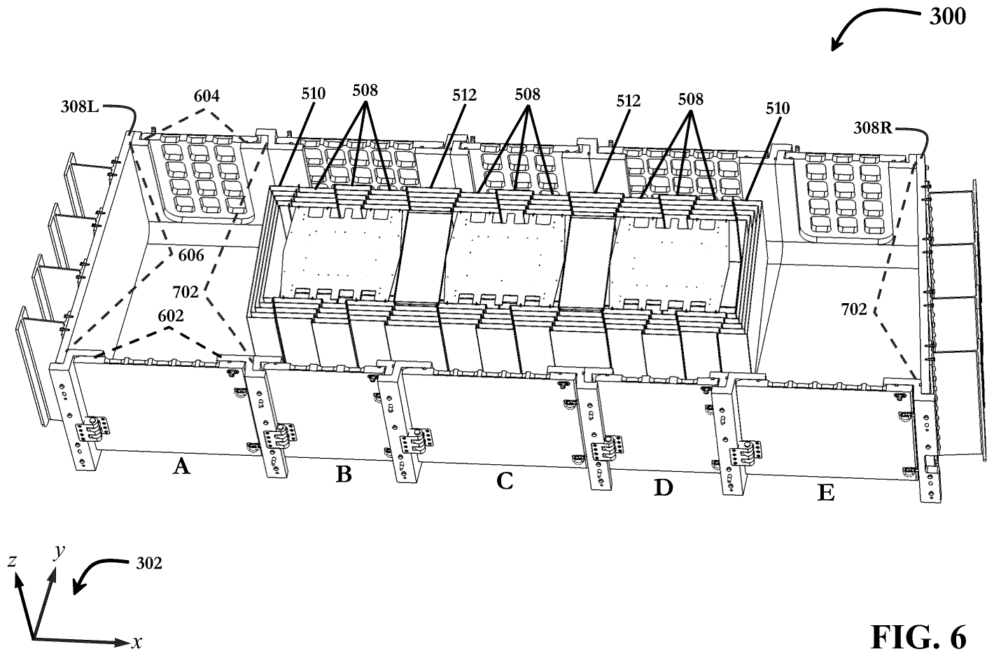

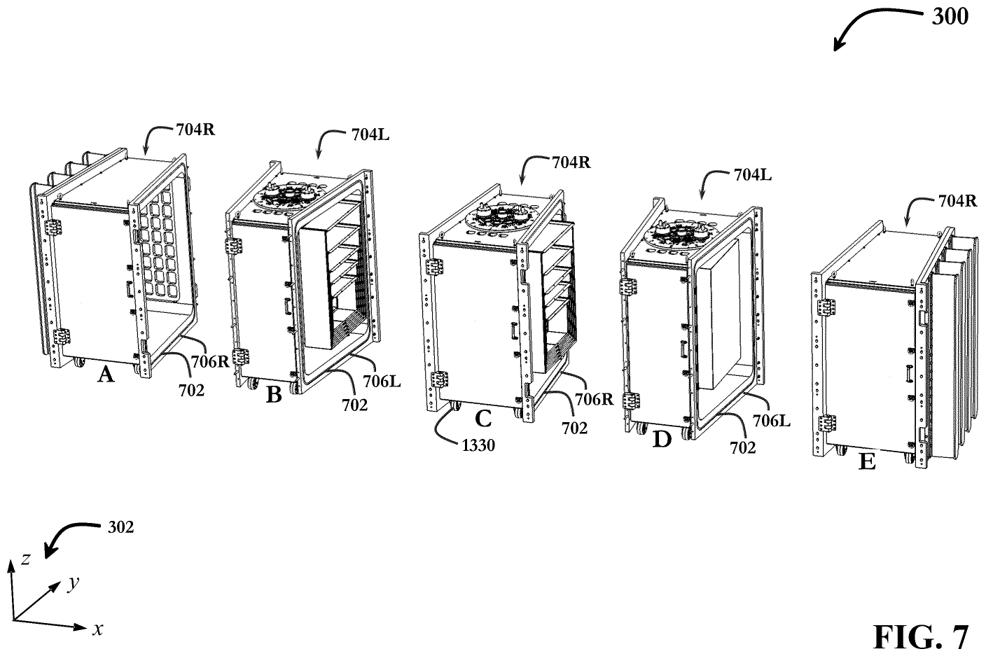

Accordingly, a first embodiment 300 is illustrated by FIG. 3, which is a perspective view thereof, shown with respect to an imaginary, Cartesian xyz coordinate system 302. Embodiment 300 is further illustrated by FIG. 4, which is a top, orthographic view parallel to the xy plane of coordinate system 302; by FIG. 5, which is a perspective view that is cutaway parallel to the xz plane of coordinate system 302; by FIG. 6, which is a perspective view that is cutaway parallel to the xy plane of coordinate system 302; and by FIGS. 7-10, which are various perspective views that are artificially exploded along the x-axis of coordinate system 302. Referring to FIGS. 3 and 4, embodiment 300 can comprise an array of unit cells 304A, 304B, 304C, 304D and 304E that are arrayed at pitch p along the x direction of coordinate system 302. For a typical application, pitch p can be about 1000 mm. Cell 304A is an unpopulated, left-end unit cell; 304B is a populated, left-thermal-shield unit cell; 304C is a populated, default unit cell; 304D is a populated, right-thermal-shield unit cell; and 304E is an unpopulated, right-end unit cell. For brevity, these different variants of unit cell 304 can be referred to succinctly by alphabetic suffix alone; that is, 304A may be referred to as “A”, 304B as “B”, 304C as “C”, 304D as “D”, and 304E as “E”. Each pair of adjacent cells {A B C D E} can be abutted to form a vacuum-tight seal therebetween by means of an O-Ring 702, as illustrated on FIG. 7.

The unit-cell array {A B C D E} shown in FIGS. 3 through 10 is merely exemplary. Other possible arrangements can include, {A B D E}, {A B C₁ C₂ D E}, {A B C₁ C₂ C₃ D E}, and more generally {A B C₁ C₂ . . . Cₙ D E}, where C₁, C₂, . . . , Cₙ are instances of C and n is any integer greater than or equal to zero. That is, the cell array can comprise n+2 populated cells {B C₁ C₂ . . . Cₙ D} and two unpopulated cells {A E}.

Referring to FIG. 4, each unit cell 304 is trapezoidal in shape as viewed normal to the xy plane, where the trapezoidal included angle is 2θ (i.e., half angle θ). The trapezoidal shapes are interleaved as shown: the wide ends of cells A, C, E are at the bottom of FIG. 4, whereas the wide ends of cells B, D are at the top of FIG. 4. The “front” of a cell is defined as the wide end of the trapezoid, such that the “right” side of cell A, C, or E is the +x side, whereas the “right” side of cell B or D is the −x side.

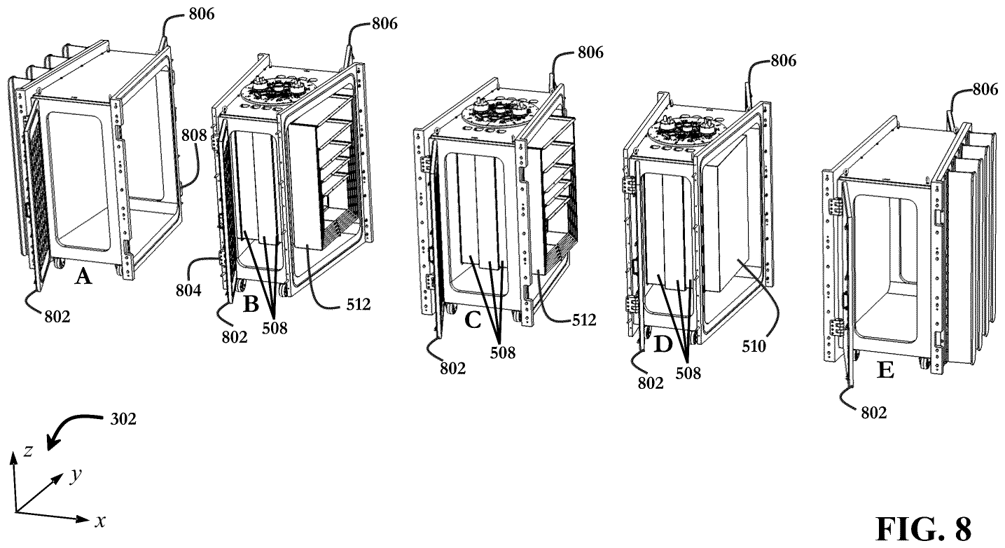

Referring to FIG. 8, each unit cell can comprise a front-door 802 that rotates about an axis parallel to the z direction by means of a plurality of front hinges 804. Likewise, each unit cell can comprise a rear-door 806 that rotates about an axis parallel to the z direction by means of a plurality of rear hinges 808. In FIGS. 3 through 7, all doors are shown in a closed position, whereas in FIGS. 8-10, all doors are shown in a partially open position, thereby to reveal equipment within the unit cells.

Referring to FIG. 7, each unit cell A, C, E can comprise a right-handed frame assembly 704R in which O-ring 702 rests in a right-side O-ring groove 706R machined into a right flange of 704R. Likewise, each unit cell B or D can comprise a left-handed frame assembly 704L in which O-Ring 702 rests in a left-side O-ring groove 706L machined into a left flange of 704L. The two versions of the frame assembly, 704R and 704L, can be otherwise identical; the only difference between them can be the location of the O-ring groove.

Various cells comprise additional elements, many of which are described in detail later. Briefly, referring to FIG. 3, unpopulated left-end cell A (i.e., 304A) can comprise a left-end-wall assembly 306L that can comprise a left-end wall 308L; likewise, unpopulated right-end cell E (i.e., 304E) can comprise a right-end-wall assembly 306R that can comprise a right-end wall 308R. Referring to FIG. 5, each populated cell B, C, or D can comprise a standard, off-the-shelf dilution-refrigerator assembly 502. As currently illustrated, refrigerator 502 is a BlueFors XLD-1000, manufactured by BlueFors Oy of Helsinki, Finland; however, other standard refrigerators may be used. With the refrigerator illustrated, unit-cell-to-unit-cell pitch p can be 1000 mm. Still referring to FIG. 5, each populated cell B, C, D can further comprise (as called out for cell B only) an array of custom thermal flanges 504, one for each of the previously described cryogenic temperatures T₁, T₂, T₃, T₄, and T₅, that can be affixed, respectively, to a set of standard thermal flanges 506 of refrigerator 502. Each populated cell B, C, D can further comprise an array of default thermal shields 508 that are removably affixed to flanges 504. Cell B can additionally comprise, on its right (−x) side, a first array of end thermal shields 510, and on its left (+x) side, a first array of bridge shields 512 that bridge between cells B and C. Cell C can additionally comprise, on its +x side, a second set of bridge shields 512 that bridge between cells C and D. Cell D can additionally comprise, on it's +x side, a second array of end thermal shields 510.

The arrays of flanges 504 and thermal shields 508, 510, 512 together create, as illustrated in FIG. 6, a set of substantially closed, nested thermal shells, as required for successful operation of a dilution refrigerator, lest radiation from higher-temperature shells overwhelm the cooling capacity of a lower-temperature stage. FIG. 6 also illustrates that abutted frames 704L and 704R, together with doors 802 and 806 and end walls 306L and 306R, formed a close, vacuum-tight shell, because, as illustrated on FIG. 6, abutted frames 704 and right-end wall 308R seal to each other with frame O-rings 702; each front door 802 seals to frame 704 with a front-door O-ring 602; each rear door 804 seals to frame 704 with a rear-door O-ring 604, and left-end wall 308L seals to abutted frame 704 with an end-wall O-Ring 606.

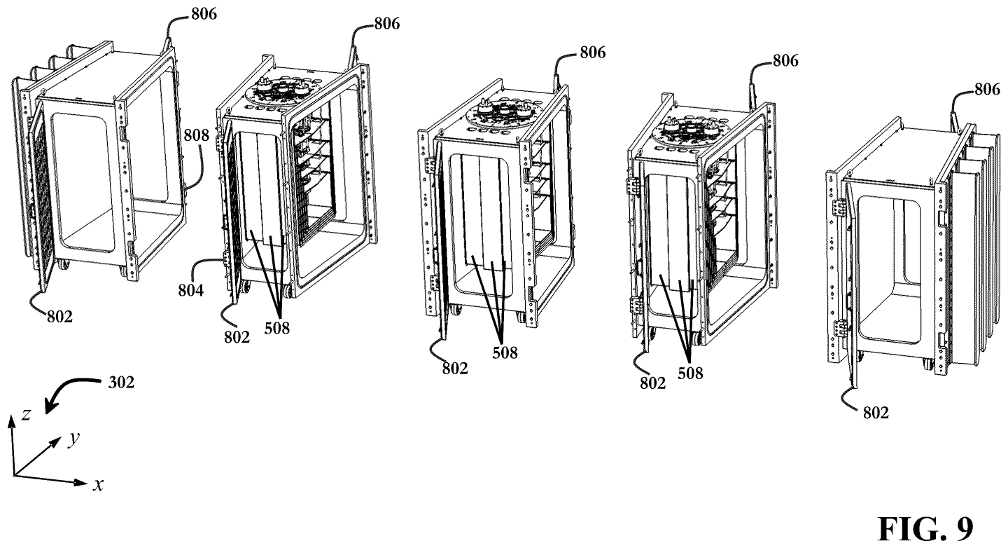

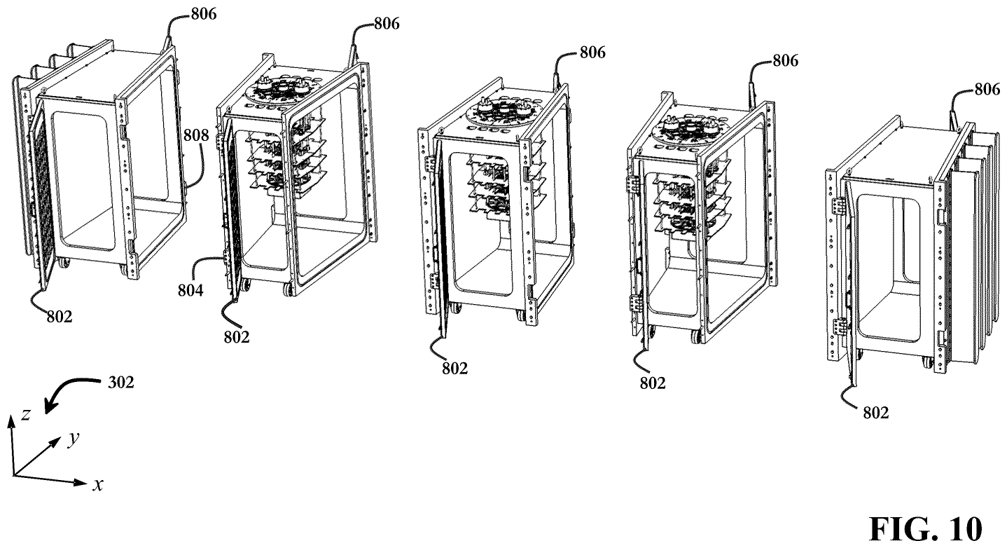

The structure of embodiment 300 is clarified by additional views thereof on exploded FIGS. 7 through 10: on FIG. 7, doors 802 and 806 are closed; FIG. 8 is identical to FIG. 7 except the doors are open; FIG. 9 is identical to FIG. 8 except that end shields 510 and bridge shields 510 are hidden; FIG. 10 is identical to FIG. 9 except that default shields 506 are also hidden. For convenience, the designation 704 shall be used to describe either right-handed from 704R or left-handed frame 704L.

Referring to FIG. 5, each populated cell B, C, D can further comprise at least one quantum payload 514. To allow payloads 514 to communicate electrically with equipment external to the unit-cell array, each populated cell B, C, D can further comprise vertical wiring means (not shown) that travel vertically in a plurality of cable cutouts 516, as illustrated by arrow 518, and which exit the unit cell in a vacuum-tight manner through a plurality of cable feedthroughs 402 (FIG. 4) at the top of frame 704 (FIG. 7). To allow payloads 514 to communicate electrically with each other, embodiment 300 can further comprise horizontal wiring means 520, such as aforementioned L-coupler cables, that travel between payloads. An advantage of one or more embodiments is that the unit-cell-to-unit-cell pitch p can be relatively small (e.g., 1000 mm), thereby allowing the L-coupler cables that extend between adjacent unit cells to be relatively short. Details of wiring means 518 and 520 are not described herein, thereby to emphasize that embodiment 300 is flexible regarding the details of electrical wiring: the payloads 514 and shields 508 and 512 may be modified as required to accommodate various arrangements of horizontal wiring 520, and custom thermal flanges 504 can be modified as required to accommodate various arrangements of vertical wiring 518. Thus, embodiment 300 is amenable to a wide variety of quantum-computing needs, as well as to applications unrelated to quantum computing.

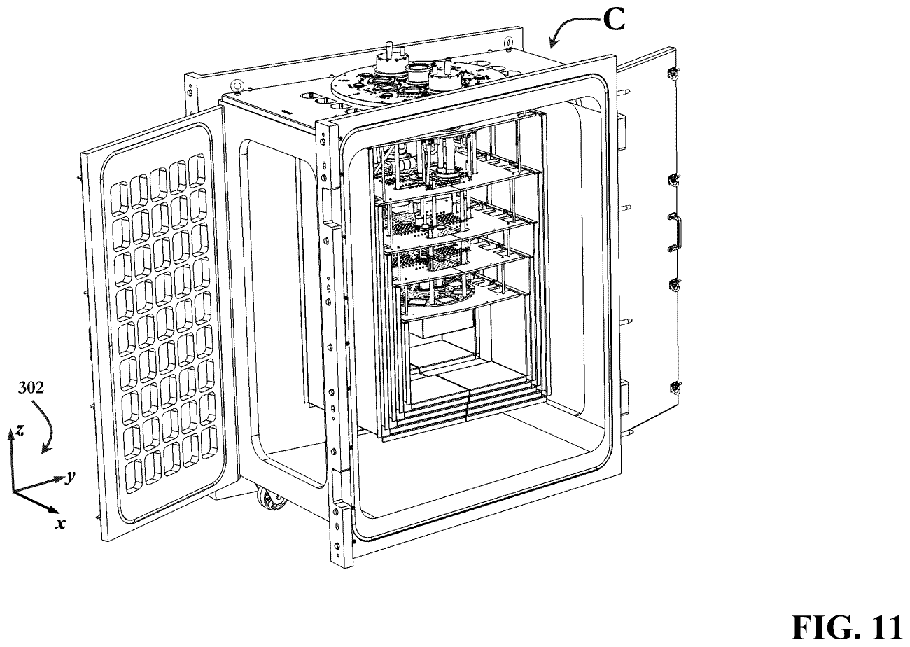

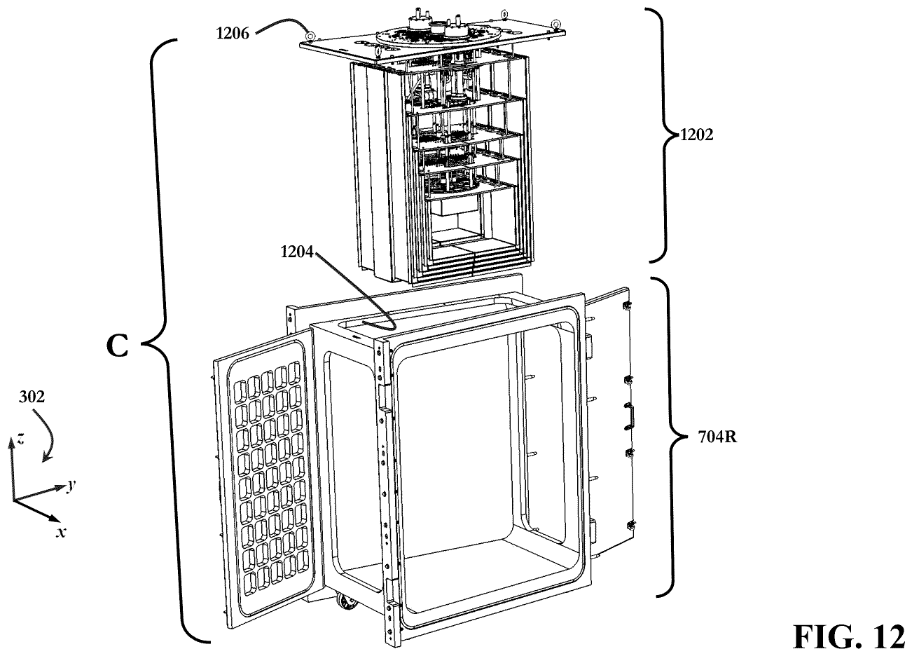

To further describe the details of a populated cell (B, C, or D), unit-cell C is used as an example. It is illustrated in FIG. 11 as in FIG. 9, assembled, with bridge shields 512 hidden. As further illustrated in FIG. 12, unit cell C can comprise frame assembly 704R (previously discussed in connection with FIG. 7) and an insert assembly 1202. As illustrated in FIG. 12, insert assembly 1202 can be vertically inserted into, and vertically withdrawn from, frame assembly 704R through a skylight cutout 1204 at the top of frame assembly 704R. Insertion and withdrawal can be accomplished by means of a gantry crane (not shown) that can attach to a plurality of lift points 1206.

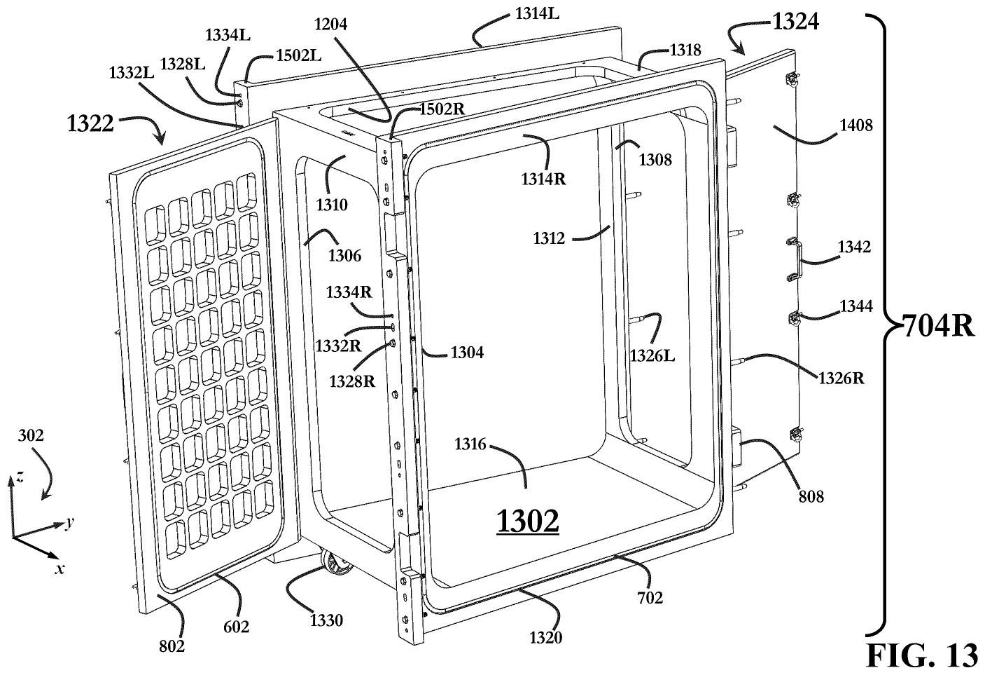

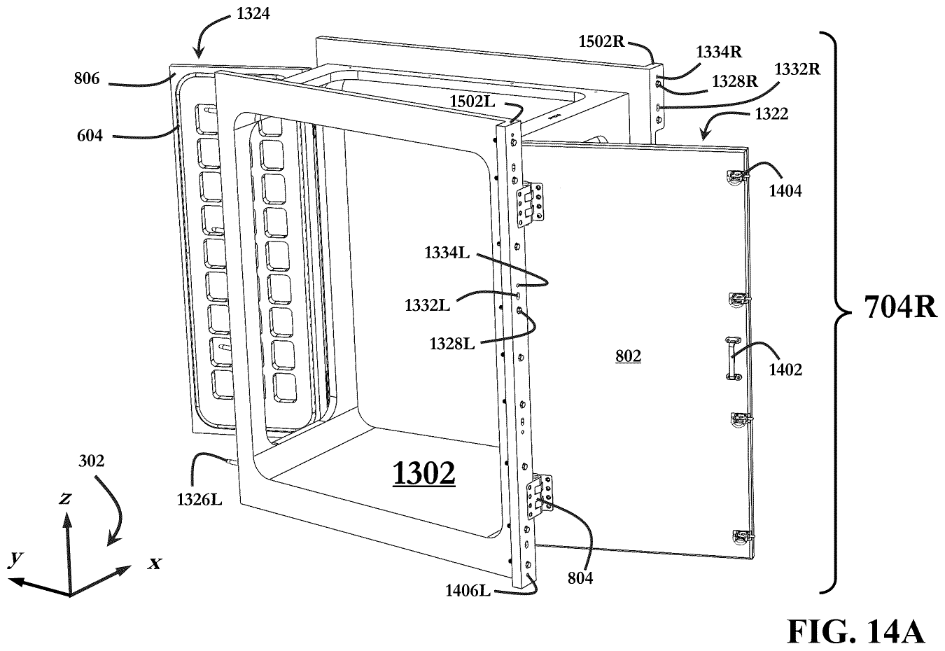

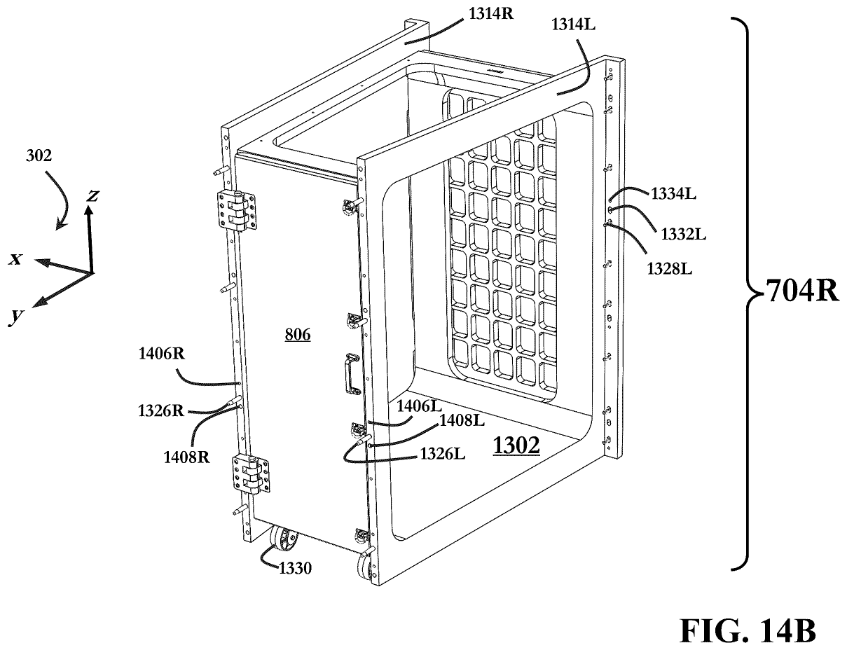

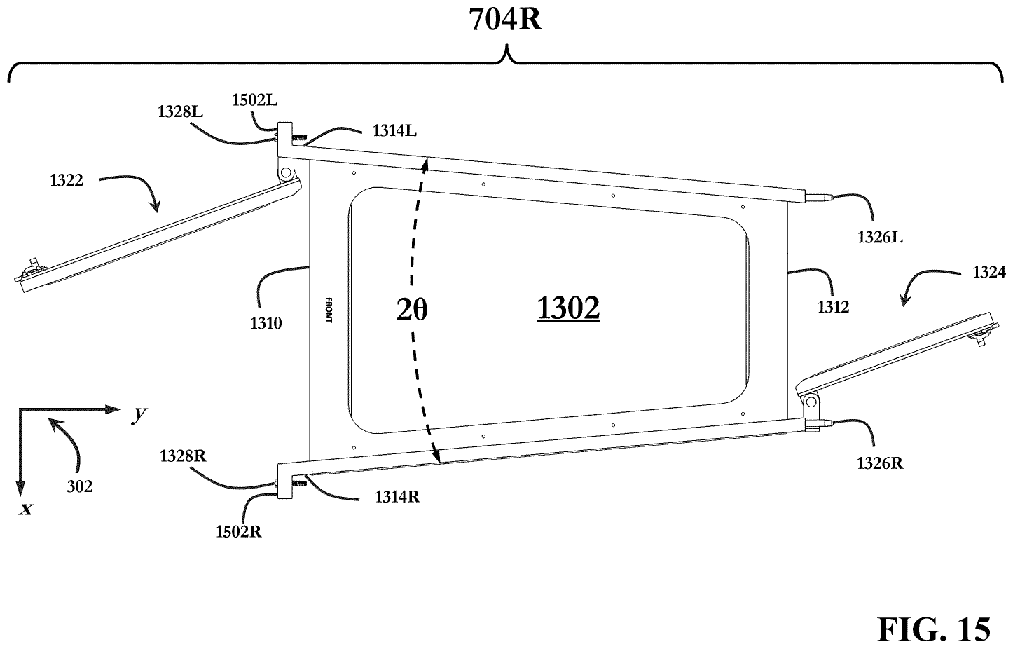

Frame assembly 704R is illustrated in FIGS. 13, 14A, 14B, and 15. FIG. 13 is a right-front perspective view, FIG. 14A is a left-front perspective view, FIG. 14B is a rear perspective view, and FIG. 15 is a top view. Referring to FIG. 13, frame assembly 704R can comprise a frame 1302, which can be a shell-like structure comprising a side cutout 1304 through its +x and −x faces, a front cutout 1306 through its −y face, a rear cutout 1308 through its +y face, and skylight cutout 1204 through its +z face. Thus, frame 1302 can comprise a cutout front wall 1310, a cutout rear wall 1312, a cutout left wall 1314L, a cutout right wall 1314R, a solid bottom wall 1316, and a cutout top wall 1318. Referring to FIG. 15, the shape of frame 1302 can be trapezoidal, whereby the angle 2θ can be subtended between left wall 1314L and right wall 1314R. Left wall 1314L can comprise a left-projecting flange 1502L and right wall 1314R can comprise a right-projecting flange 1502R. Referring to FIG. 13, right wall 1314R can comprise, a frame-O-ring groove 1320 to accommodate frame O-ring 702.

Referring to FIGS. 13-15, frame assembly 704R can further comprise a front-door assembly 1322, a rear-door assembly 1324, frame O-ring 702 that is accommodated by frame-O-ring groove 1320, a plurality of left guide pins 1326L that are pressed into holes in a rear surface of left wall 1314L, a plurality of right guide pins 1326R that are pressed into holes into a rear surface of right wall 1314R, a plurality of left draw screws 1328L that are accommodated by clearance holes in left-projecting flange 1502L, a plurality of right draw screws 1328R that are accommodated by clearance holes in right-projecting flange 1502R, and a plurality of casters 1330 that allow cell assembly C to roll easily upon a floor.

Referring to FIGS. 13 and 14A, frame 1302 can further comprise, in the left projecting flange 1502L, a plurality of left guide-pin clearance holes 1332L and a plurality of left jack-screw tapped holes 1334L. Likewise, referring to FIG. 13, frame 1302 can comprise, in the right projecting flange 1502R, a plurality of right guide-pin clearance holes 1332R and a plurality of right jack-screw tapped holes 1334R. Referring to FIG. 14B, frame 1302 can further comprise, at the rear of left wall 1314L, a plurality of left, draw-screw tapped holes 1406L and a plurality of left jack-screw bearing areas 1408L. Likewise, frame 1302 can further comprise, at the rear of right wall 1314R, a plurality of right, draw-screw tapped holes 1406R and a plurality of right jack-screw bearing areas 1408R.

Referring to FIGS. 13, front-door assembly 1322 can comprise front door 802 and front-door O-ring 602. Referring to FIG. 14A, front-door assembly 1322 can further comprise the plurality of front hinges 804 that allow front door 802 to rotate about an axis parallel to the z direction, a front handle 1402 to aid in opening front door 802, and at least one front latch 1404 to aid in sealing front door 802 when closed.

Likewise, referring to FIG. 14A, rear-door assembly 1324 can comprise rear door 804 and rear-door O-ring 604. Referring to FIG. 13, rear-door assembly 1324 can further comprise the plurality of rear hinges 808 that allow rear door 806 to rotate about an axis parallel to the z direction, a rear handle 1336 to aid in opening rear door 1408, and at least one rear latch 1338 to aid in sealing door 1408 when closed.

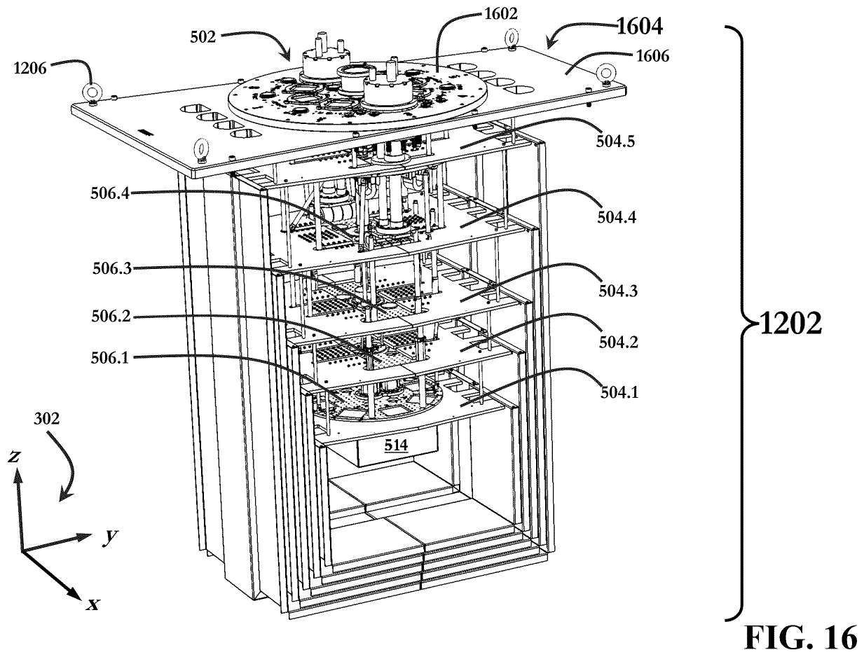

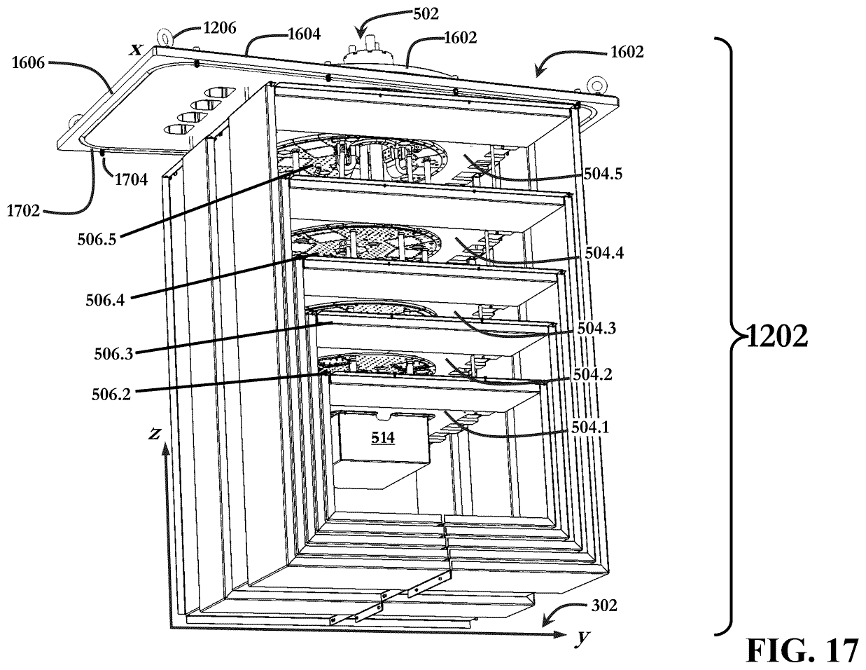

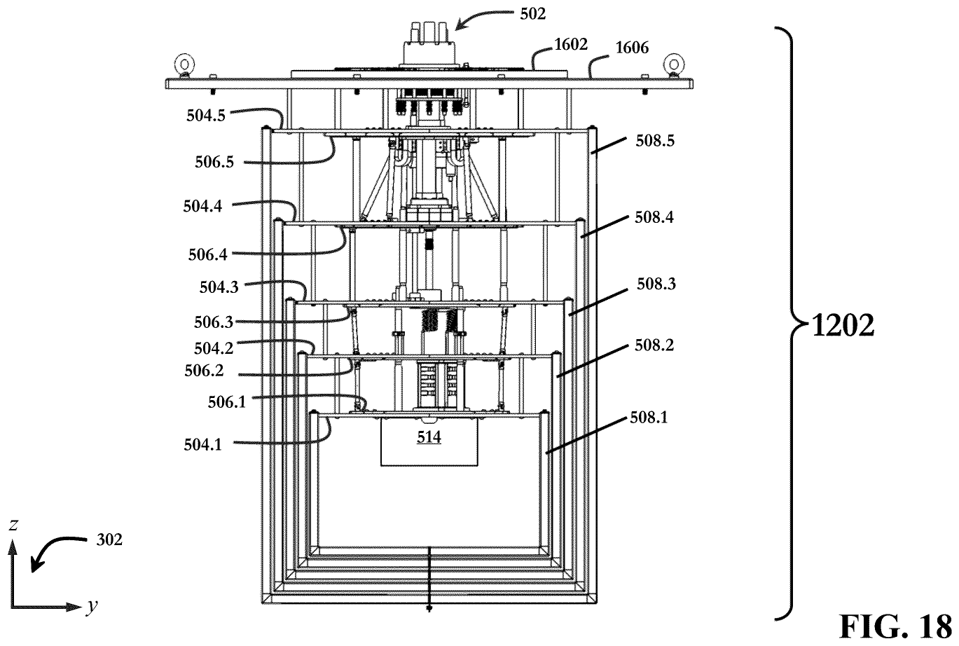

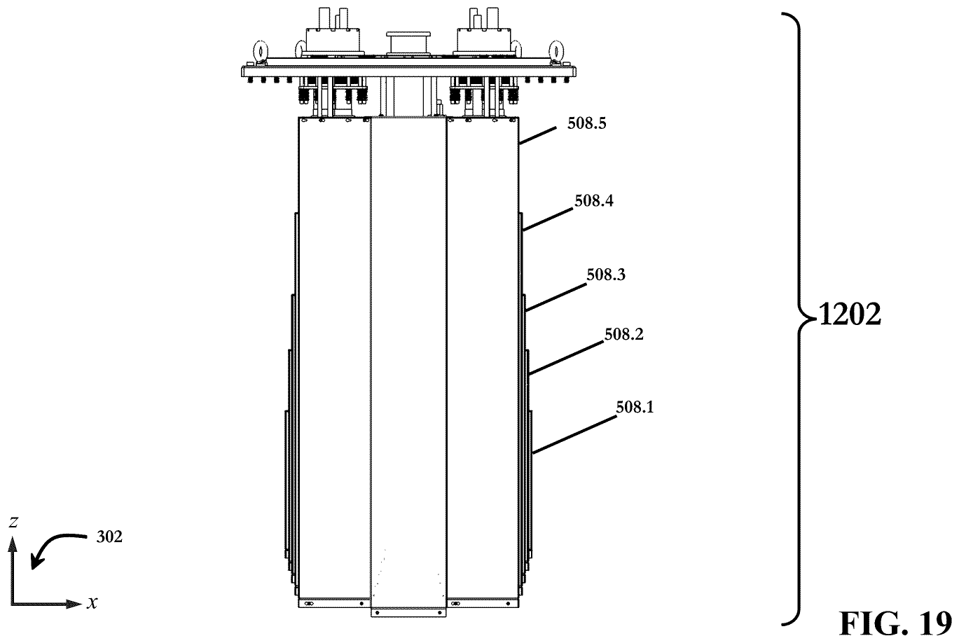

Insert assembly 1202 is illustrated in FIGS. 16-19: FIG. 16 is a first perspective view, FIG. 17 is second perspective view, FIG. 18 is an orthographic view parallel to the yz plane of coordinate system 302; and FIG. 19 is an orthographic view parallel to the xz plane of coordinate system 302. Referring to FIGS. 16 through 18, insert assembly 1202 can comprise commercial dilution refrigerator 502, which comprises a room-temperature flange 1602, as well as previously described cryogenic thermal flanges 506. Insert assembly 1202 can further comprise a skylight assembly 1604. Skylight assembly 1604 can comprises a skylight plate 1606 that supports room temperature flange 1602, but which allows passage of flanges 506 when refrigerator 502 is inserted through skylight plate 1606 from the +z direction. Referring to FIG. 17, skylight assembly 1604 can further comprise a skylight O-ring 1702, and a plurality of skylight screws 1704 that cause skylight 1606 to vacuum seal to top wall 1320 of frame 1302. Skylight assembly 1604 can further comprise the plurality of lift points 1206 affixed to skylight plate 1604.

Insert assembly 1202 can further comprise the array of custom flanges 504 previously illustrated in FIG. 5; this array can comprise a first custom flange 504.1 that is affixed to a first-temperature flange 506.1 of dilution refrigerator 502, a second custom flange 504.2 that is affixed to a second-temperature flange 506.2 of dilution refrigerator 502, a third custom flange 504.3 that is affixed to a third-temperature flange 506.3 of dilution refrigerator 502, a fourth custom flange 504.4 that is affixed to a fourth-temperature flange 506.4 of dilution refrigerator 502, and a fifth custom flange 504.5 that is affixed to a fifth-temperature flange 506.5 of dilution refrigerator 502. During operation of embodiment 300, refrigerator 502 holds temperature flanges 506.1, 506.2, 506.3, 506.4, and 506.5 at temperatures T₁, T₂, T₃, T₄, and T₅, respectively, where T₁<T₂<T₃<T₄<T₅. Typical values of these temperatures are as follows: T₁=20 mK, T₂=100 mK, T₃=700 mK, T₄=4K, T₅=50K. An advantage of one or more embodiments such as embodiment 300 is that, in the long-run deployment of thereof, as needs change, custom flanges 504, which unlike flanges 506 are not entangled with the refrigerator's cooling equipment, can be removed and replaced with different versions thereof without replacing or disturbing refrigerator 502 itself.

Referring to FIG. 18, insert assembly 1202 can further comprise cryogenic payload 514 that can be affixed to custom flange 504.1, as well as a nested array of default thermal shields 508 previously illustrated in FIG. 5. The array of thermal shields 508 can comprise a first set of thermal shields 508.1 that is removably affixed to flange 504.1, a second set of thermal shields 508.2 that is removably affixed to flange 504.2, a third set of thermal shields 508.3 that is removably affixed to flange 504.2, a fourth set of thermal shields 508.4 that is removably affixed to flange 504.4, and a fifth set of thermal shields 508.5 that is removably affixed to flange 504.5.

To illustrate further the construction of the nested array of default thermal shields 508, as well as the similar array of bridge thermal shields 512, and the array of end shields 510, all previously described in connection with FIGS. 5 and 6, it is useful to focus on a single layer of the nest, each of which forms a substantially closed “thermal shell” that comprises all of the flanges and shields at one of the temperatures T₁ through T₆.

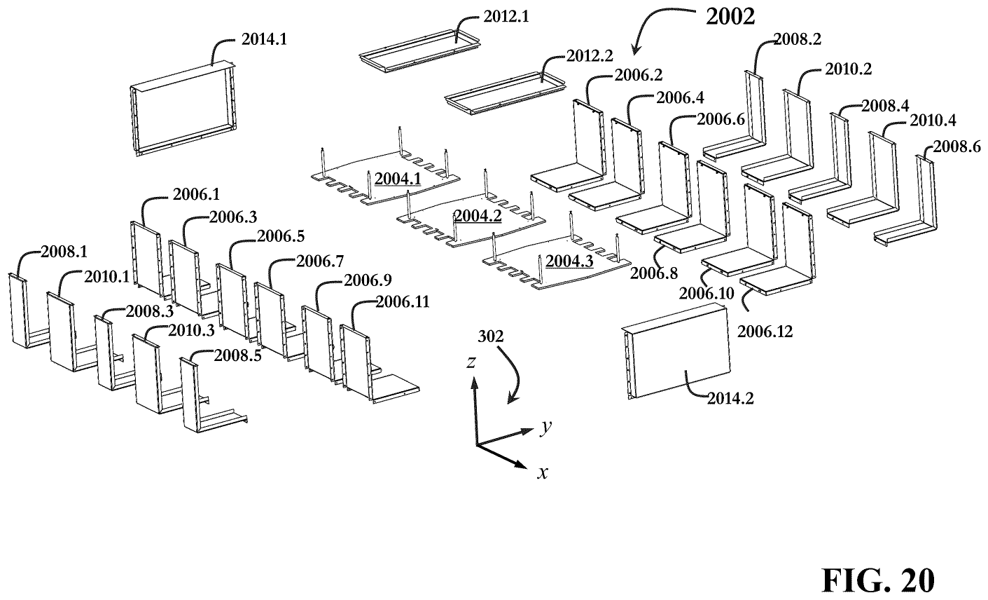

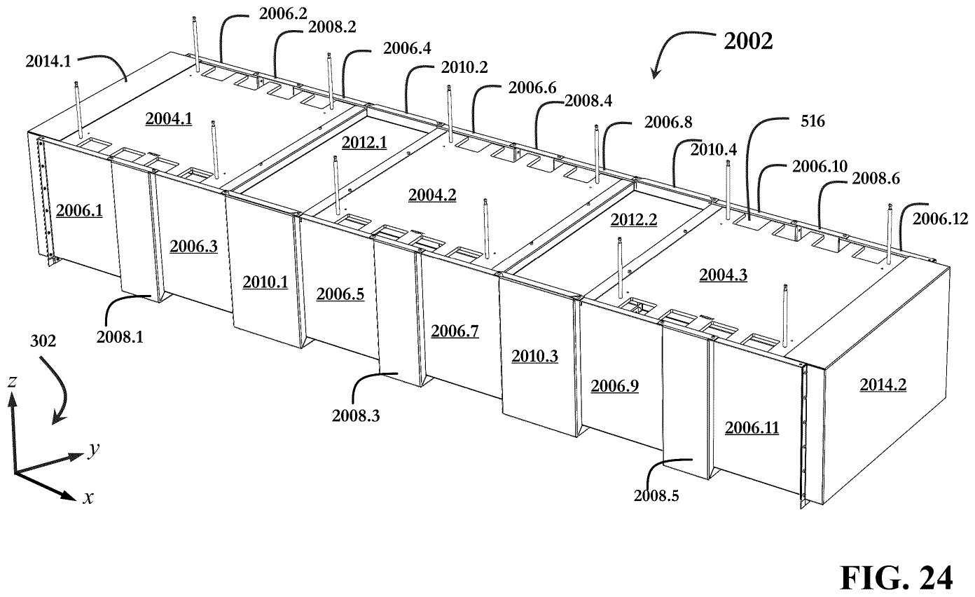

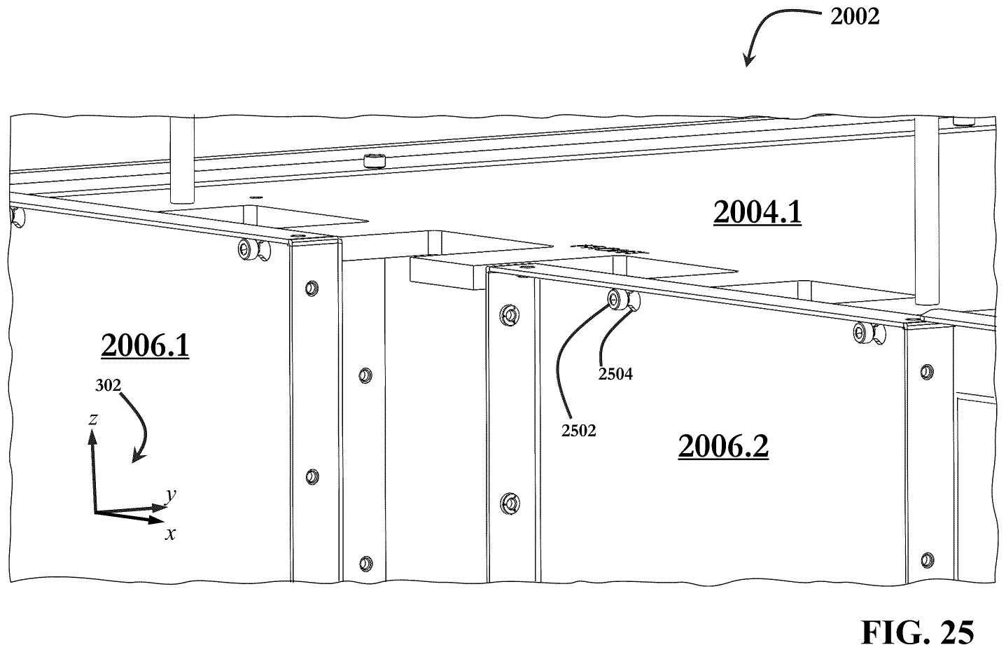

For example, FIGS. 20-28 illustrate, for embodiment 300, an innermost thermal shell 2002 that corresponds to the lowest cryogenic temperature T₁. Thermal shells at the other cryogenic temperatures T₂, T₃, T₄, T₅ are similar. FIGS. 20-23 illustrate various exploded views of thermal shell 2002; FIG. 24 illustrates an assembled view thereof; and FIGS. 25-29 illustrate various means for connecting elements thereof. Referring to FIG. 20, thermal shell 2002 can comprise, for each of the three populated cells B, C, D of embodiment 300, a thermal flange 2004 (denoted 2004.1 for cell B, 2004.2 for cell C, and 2004.3 for cell C, each being an instance of what was previously referred to on FIG. 5 as 504.1); four instances of a lateral shield 2006 (denoted 2006.1, 2006.2, 2006.3, and 2006.4 for cell B; 2006.5, 2006.6, 2006.7, and 2006.8 for cell C; and 2006.9, 2006.10, 2006.11, and 2006.12 for cell C); and two instances of a central shield 2008 (denoted 2008.1 and 2008.2 for cell B, 2008.3 and 2008.4 for cell C, and 2008.5 and 2008.6 for cell D). Thermal shell 2002 can further comprise, to span the gap between cells B and C, a first pair of instances 2010.1 and 2010.2 of a side-bridge shield 2010, and a first instance 2012.1 of a top-bridge shield 2012. Thermal shell 2002 can further comprise, to span the gap between cells C and D, a second pair of instances 2010.3 and 2010.4 of side-bridge shield 2010, and a second instance 2012.2 of top-bridge shield 2012. Thermal shell 2002 can further comprise two instances of an end shield 2014, including a first instance 2014.1 to complete the shell at its −x end, and a second instance 2014.2 to complete the shell at its +x end.

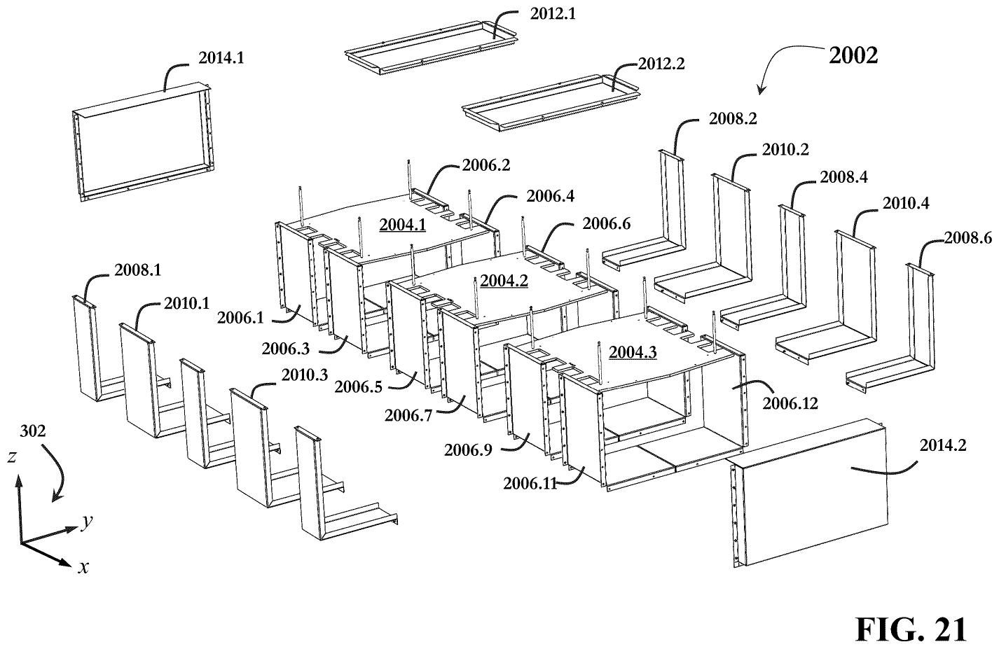

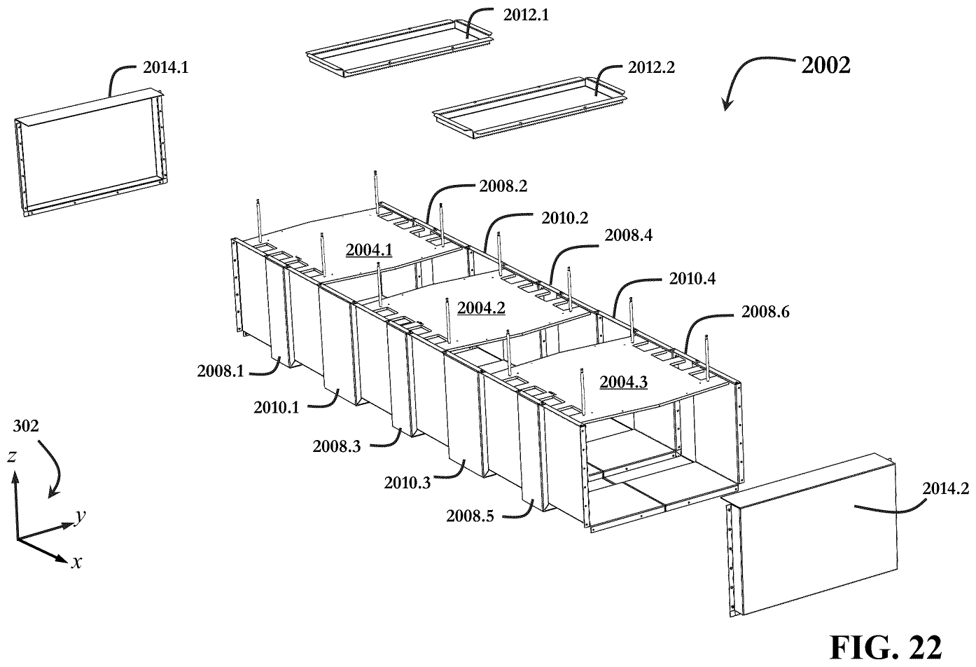

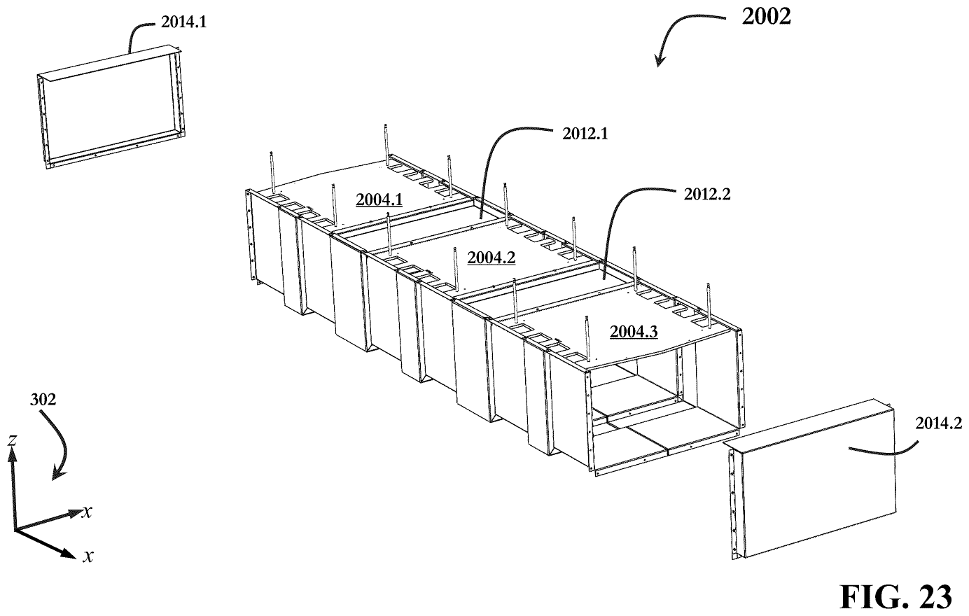

FIGS. 20-24 illustrate a step-by-step assembly of thermal shell 2002: FIG. 20 illustrates it fully exploded, FIG. 21 illustrates it after a first assembly step, FIG. 22 illustrates it after a second assembly step, FIG. 23 illustrates it after a third assembly step, and FIG. 24 represents it fully assembled.

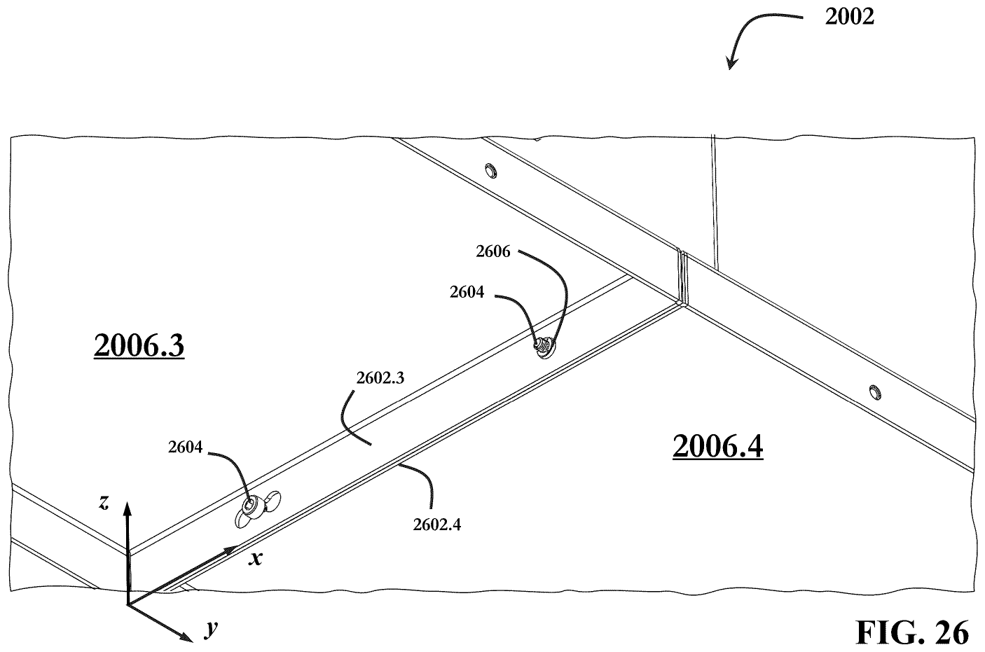

FIG. 21 illustrates the first assembly step of thermal shell 2002 in which lateral shields 2006 are mounted upon thermal flange 2004. Shields 2006 can be affixed to flange 2004 as illustrated in FIG. 25: fasteners 2502 threaded into flange 2004 can engage keyhole slots 2504 in shields 2006. As illustrated in FIG. 26, opposing shields 2006, such as shields 2006.3 and 2006.4, can be affixed to each other at the bottom: a flange 2602.3 of shield 2006.3 can abut a flange 2602.4 of shield 2006.4, and can be fastened thereto using screws 2604 and swaged nuts 2606.

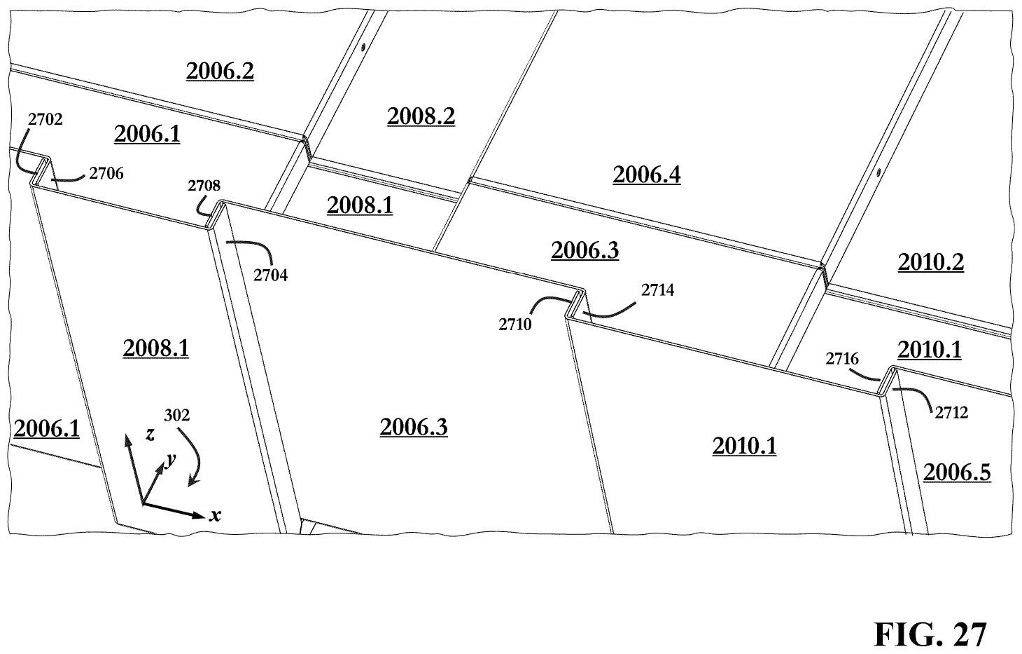

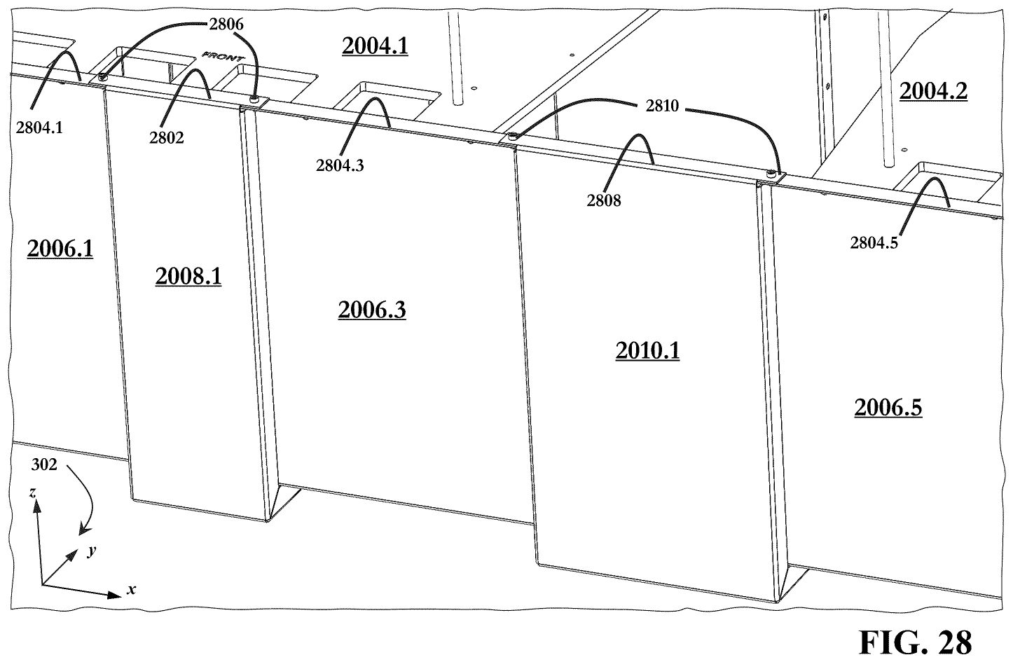

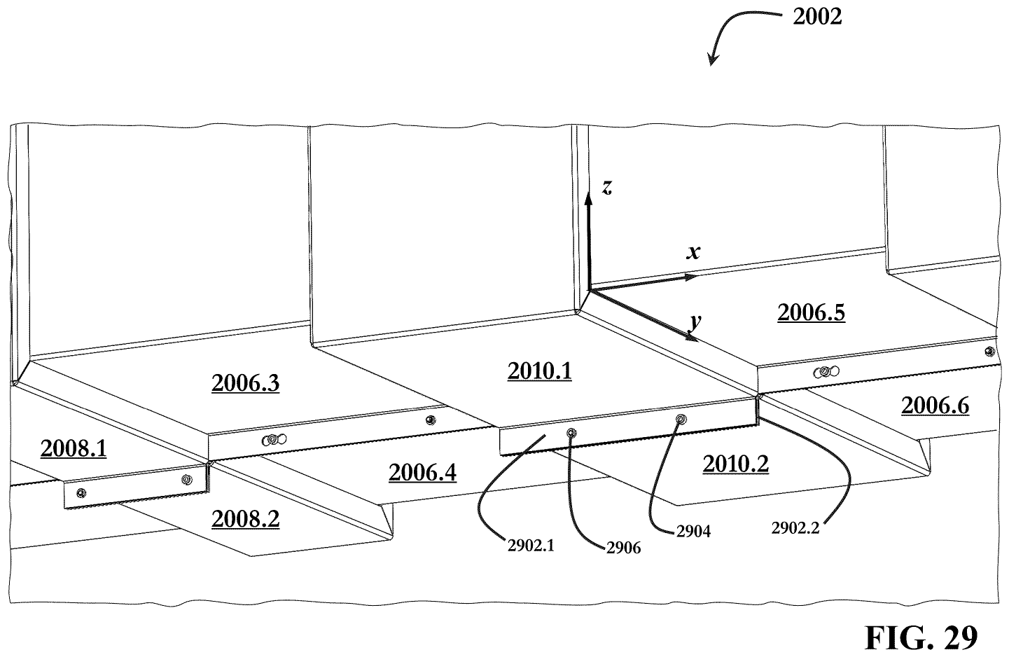

FIG. 22 illustrates the second assembly step of thermal shell 2002 in which center shields 2008 and bridge shields 2010 are mounted upon lateral shields 2006. As illustrated in FIG. 27, center shields 2008 and bridge shields 2010 can overlap lateral shields 2006, thereby to enhance radiation blockage. That is, inwardly projecting center-shield flanges 2702 and 2704 can overlap outwardly projecting lateral-shield flanges 2706 and 2708, respectively. Likewise, inwardly projecting bridge-shield flanges 2710 and 2712 can overlap outwardly projecting lateral-shield flanges 2714 and 2716, respectively. As illustrated in FIG. 28, center shields 2008 and bridge shields 2010 can be affixed to lateral shields 2006. That is, for example, an inwardly projecting flange 2802 of center shield 2008.1 can overlap outwardly projecting flanges 2804.1 and 2804.3 of lateral shields 2006.1 and 2006.3, respectively, and flange 2802 can be affixed thereto by fasteners 2806. Likewise, an inwardly projecting flange 2808 of side-bridge shield 2010.1 can overlap outwardly projecting flanges 2804.3 and 2804.5 of lateral shields 2006.3 and 2006.5, respectively, and flange 2808 can be affixed thereto by fasteners 2810. As illustrated in FIG. 29, opposing side-bridge shields 2010, such as 2010.1 and 2010.2, can be affixed to each other at the bottom: a flange 2902.1 of shield 2010.1 can abut a flange 2902.2 of shield 2010.2, and can be fastened thereto using screws 2904 and swaged nuts 2906.

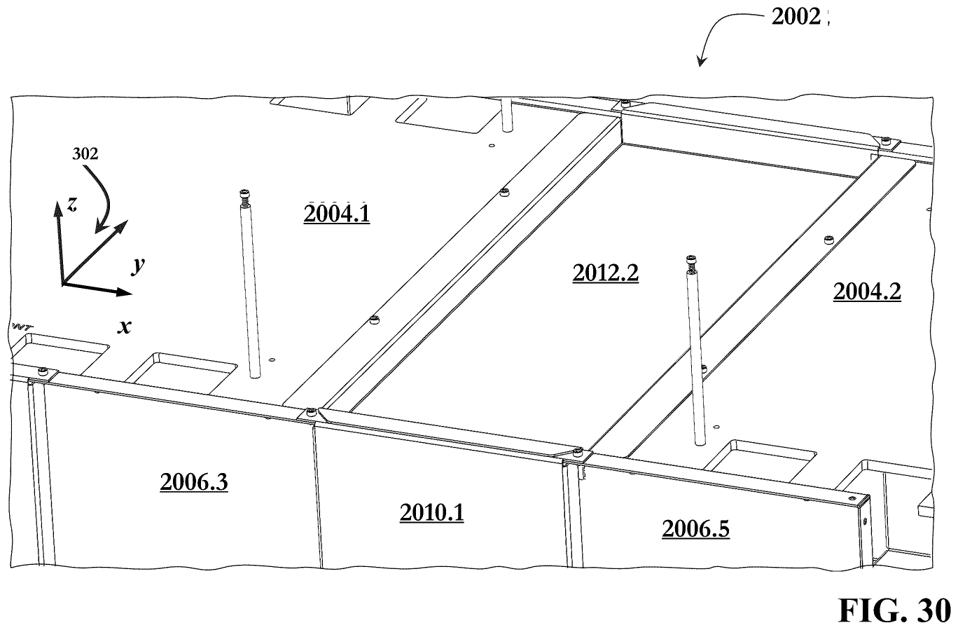

FIG. 23 illustrates the third assembly step of thermal shell 2002 in which top-bridge shields 2010 are mounted upon flanges 2004. As illustrated in FIG. 30, top-bridge shields 2012 can overlap flanges 2004 and side-bridge shields 2010, thereby to enhance radiation blockage. That is, for example, flanges 3002 and 3004 of top-bridge shield 2012.1 can overlap flanges 2004.1 and 2004.2, respectively, and can be affixed thereto with fasteners 3006. Moreover, flanges 3008 and 3010 of top-bridge shield 2012.1 can overlap side-bridge shields 2010.1 and 2010.2, respectively.

FIG. 24 illustrates thermal shell 2002 fully assembled. As shown, the shell is substantially closed, and thereby resistance to thermal radiation, except for the plurality of cutouts 516 that are used for vertical wiring, as previously mentioned in connection with FIG. 5. Such wiring, not described herein, can be packaged in a manner to occlude cutouts 516, thereby to complete the substantial closure of thermal shell 2002.

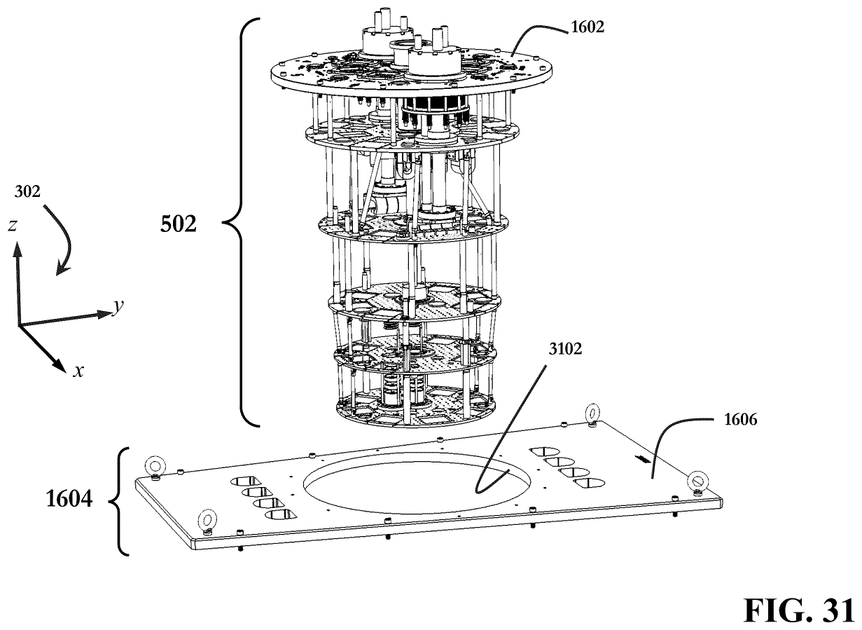

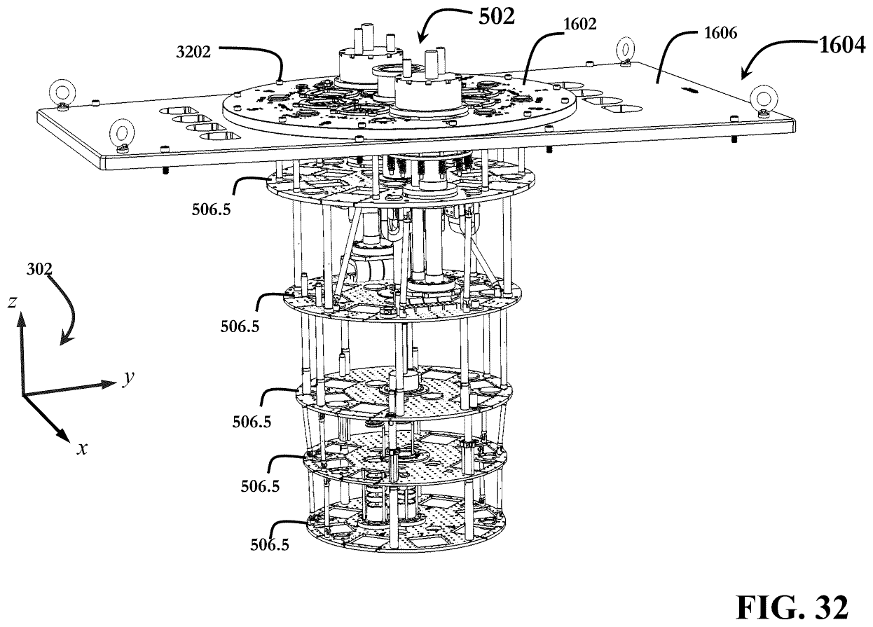

FIGS. 31-37 illustrate how off-the-shelf dilution refrigerator 502 can be retrofitted for use in embodiment 300. First, as illustrated in FIGS. 31 and 32, refrigerator 502 can be inserted into a large hole 3102 in skylight plate 1606, such that a −z face of room-temperature flange 1602 can abut a +z face of skylight plate 1606, and can be affixed thereto with fasteners 3202.

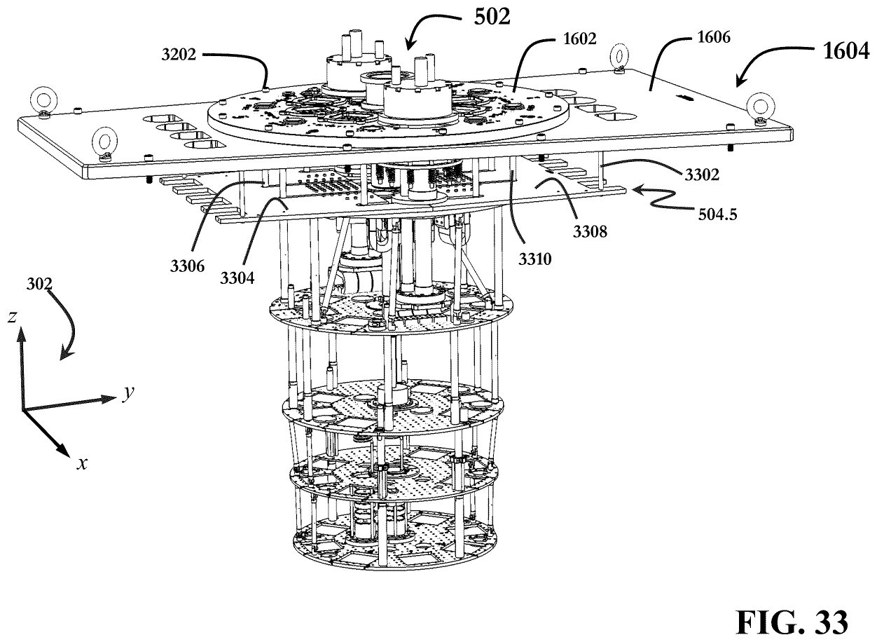

Second, as illustrated in FIG. 33, custom thermal flange 504.5 can be affixed atop the refrigerator's fifth refrigerator flange 506.5 (visible in FIG. 32) and supported by fifth-flange struts 3302. Flange 504.5 can comprise a left portion 3304 that can be inserted from the −y direction and which can be slotted to avoid interference with refrigerator elements such as a first plurality of left refrigerator struts 3306. Flange 504.5 can also comprise a right portion 3308 that can be inserted from the +y direction and which can be slotted to avoid interference with refrigerator elements such as a first plurality of right refrigerator struts 3310.

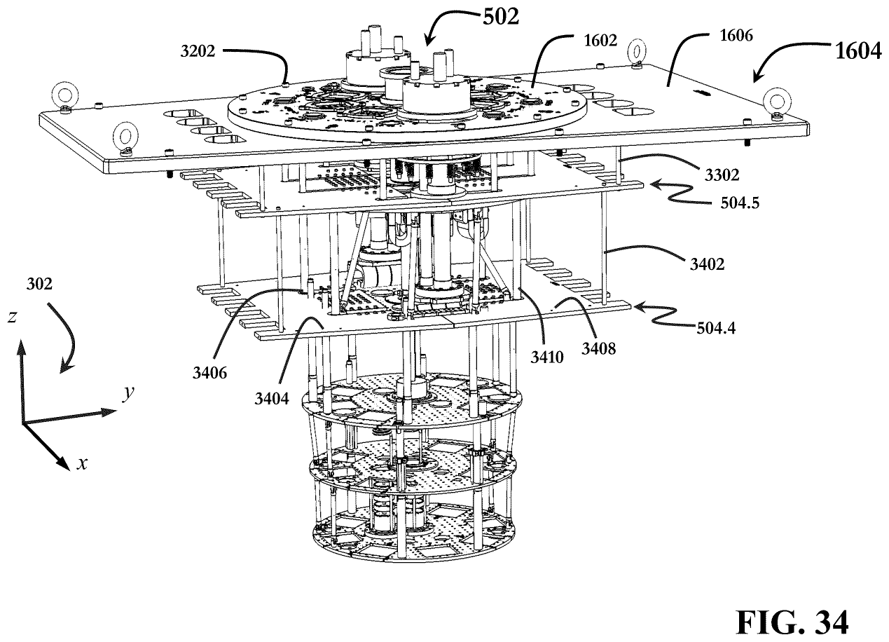

Third, as illustrated in FIG. 34, custom thermal flange 504.4 can be affixed atop the refrigerator's fourth refrigerator flange 506.4 (visible in FIG. 32) and supported by fourth-flange struts 3402. Flange 504.4 can comprise a left portion 3404 that can be inserted from the −y direction and which can be slotted to avoid interference with refrigerator elements such as a second plurality of left refrigerator struts 3406. Flange 504.4 can also comprise a right portion 3408 that can be inserted from the +y direction and which can be slotted to avoid interference with refrigerator elements such as a second plurality of right refrigerator struts 3410.

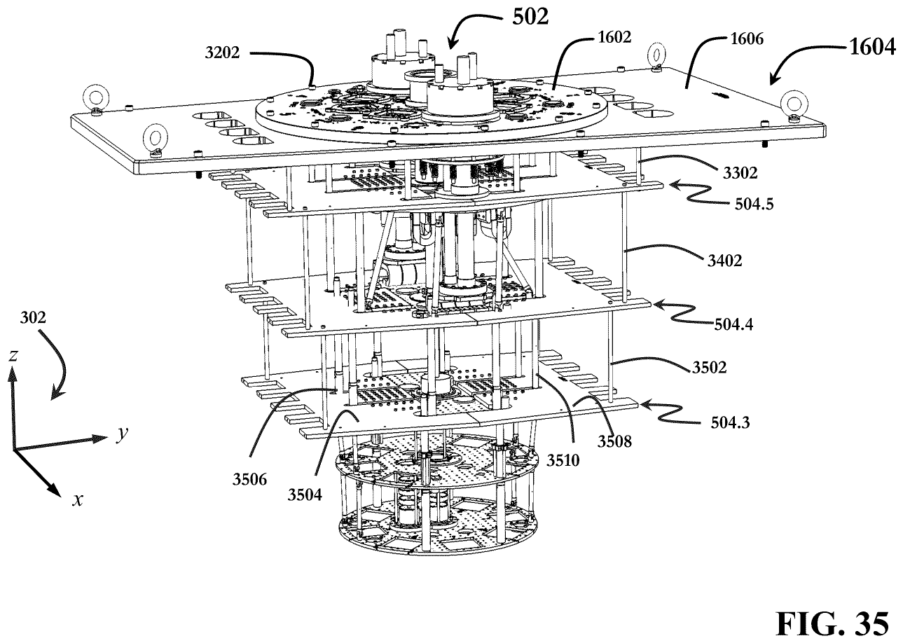

Fourth, as illustrated in FIG. 35, custom thermal flange 504.3 can be affixed atop the refrigerator's third refrigerator flange 506.3 (visible in FIG. 32) and supported by third-flange struts 3502. Flange 504.3 can comprise a left portion 3504 that can be inserted from the −y direction and which can be slotted to avoid interference with refrigerator elements such as a third plurality of left refrigerator struts 3506. Flange 504.3 can also comprise a right portion 3508 that can be inserted from the +y direction and which can be slotted to avoid interference with refrigerator elements such as a third plurality of right refrigerator struts 3510.

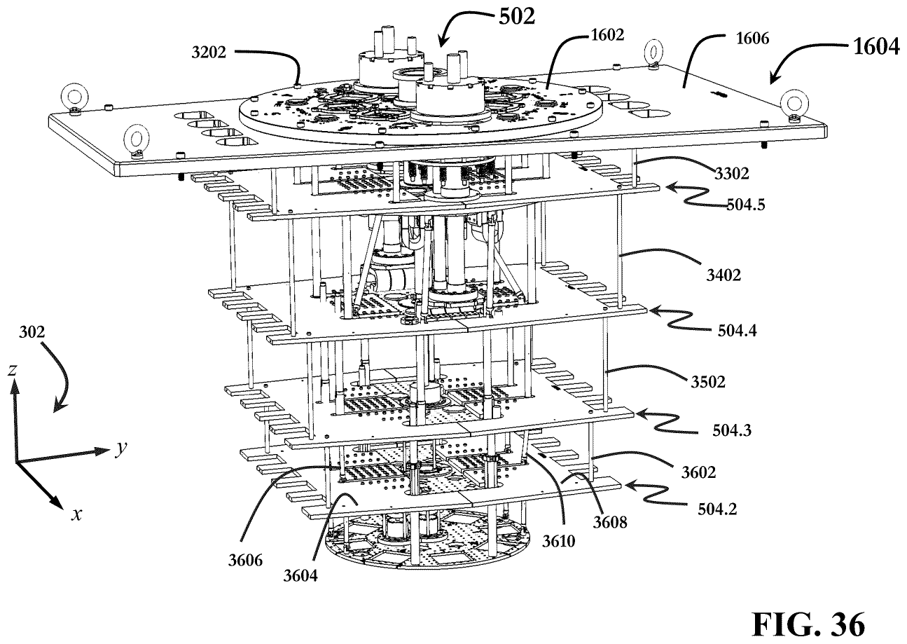

Fifth, as illustrated in FIG. 36, custom thermal flange 504.2 can be affixed atop the refrigerator's second refrigerator flange 506.2 (visible in FIG. 32) and supported by second-flange struts 3602. Flange 504.2 can comprise a left portion 3604 that can be inserted from the −y direction and which can be slotted to avoid interference with refrigerator elements such as a fourth plurality of left refrigerator struts 3606. Flange 504.2 can also comprise a right portion 3608 that can be inserted from the +y direction and which can be slotted to avoid interference with refrigerator elements such as a fourth plurality of right refrigerator struts 3610.

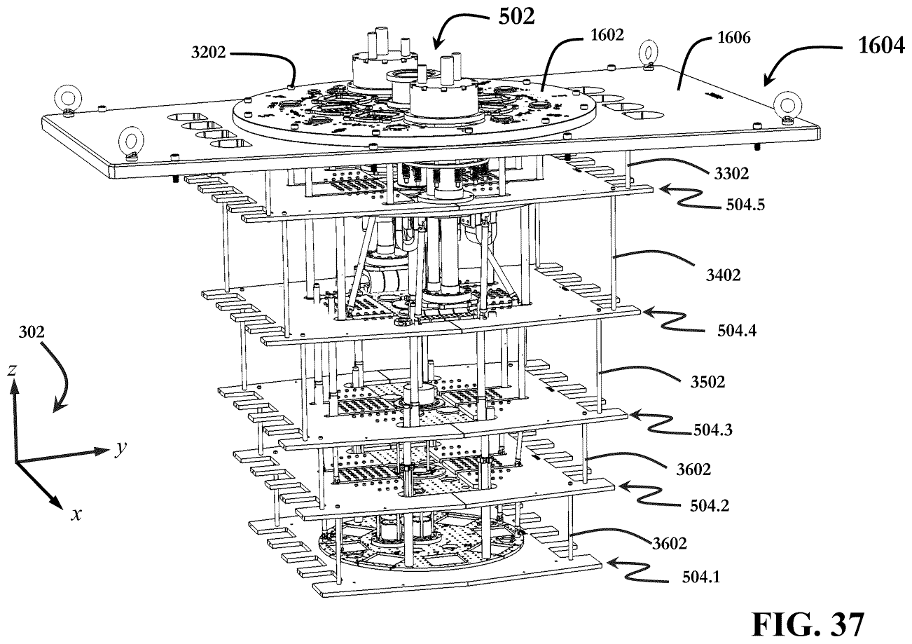

Sixth, as illustrated in FIG. 37, custom thermal flange 504.1 can be affixed beneath the refrigerator's first refrigerator flange 506.1 (visible in FIG. 32) and supported by first-flange struts 3702.

Embodiment 300 described above, which comprises just five unit cells {A B C D E}, is a relatively small example of the type of modular, scalable quantum computer envisioned, such as {A B C₁ C₂ . . . Cₙ D E}, where n can be large. Such a large modular system inevitably suffers periodic failure of failure-prone components, recovery from which is preferably fast and efficient, thereby to minimize downtime of the system. As is well known, such fast recovery is often best achieved by replacing an entire failed module rather than debugging low-level hardware in the field. Such a replaceable module is often called a field-replaceable unit, or FRU.

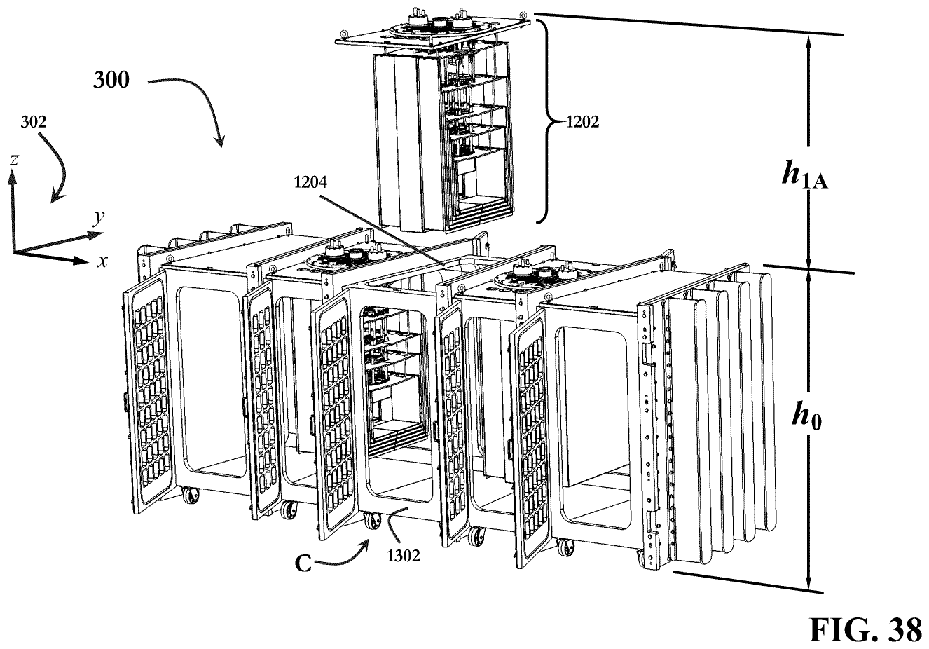

For embodiment 300 and other embodiments such as {A B C₁ C₂ . . . Cₙ D E}, one choice of FRU is insert assembly 1202, because it contains all failure-prone components in a unit cell, including refrigerator 502, payload 514, and other payload-supporting electronics. For example, according to a first FRU strategy illustrated in FIG. 38, if cell C fails, its insert assembly 1202 can be removed by withdrawing it through skylight cutout 1204 in frame 1302 and replacing it with a new instance thereof. However, this first FRU strategy can produce a first required ceiling height H₁ that is undesirably large, because it is incompatible with installation in many data centers that have relatively low ceilings. Specifically, the required ceiling height is

$${H}_{1} = {h}_{0} + {h}_{1 A} + {h}_{2} + {h}_{3} . \qquad ( 1 )$$

As illustrated on FIG. 38, h₀ is a frame height; that is, the vertical distance from a floor on which embodiment 300 rests to the top of frames 1302. As also illustrated on FIG. 38, h_{1A} is a first FRU-extraction height; that is, the vertical distance from the top of frames 1302 to the top of extracted FRU 1202. Height h₂, not shown on FIG. 38, is a supplemental height required by refrigeration equipment not shown atop assembly 1202. Height h₃, also not shown on FIG. 38, is a height required for lifting equipment, such as a gantry crane, that is needed to withdraw assembly 1202. For example, typical values can be h₀≈2.3 m, h_{1A}≈1.7 m, h₂≈1.0 m, and h₃≈1.0 m, whence

$${H}_{1} \approx 2.3 + 1.7 + 1.0 + 1.0 = 6. m , \qquad ( 1 A )$$

whereas many data centers have a clear ceiling height H* on the order of H*≈4.3 m. Consequently, the first FRU strategy illustrated on FIG. 38 is not viable for typical data centers.

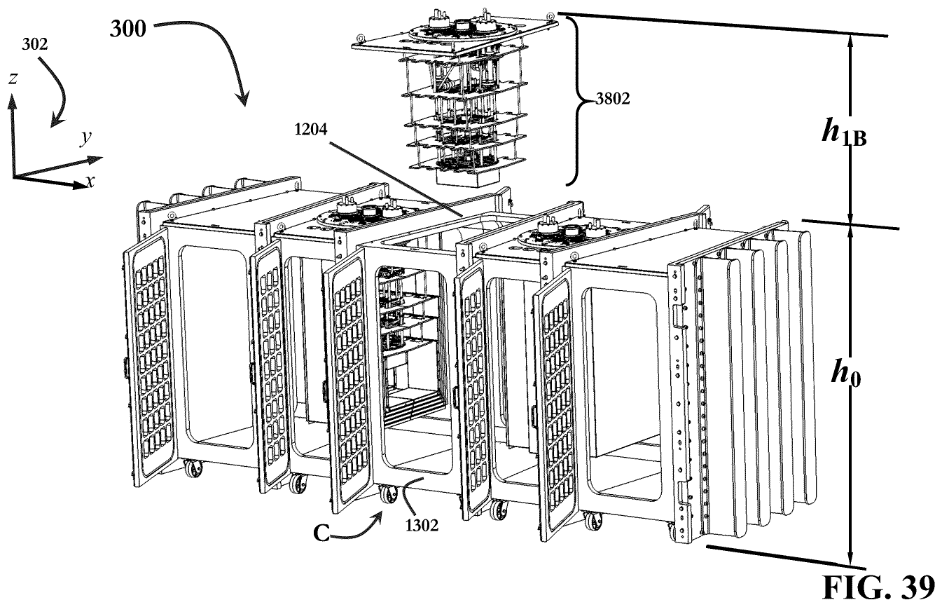

Required ceiling height can be reduced somewhat by a second FRU strategy, illustrated in FIG. 39, in which, prior to withdrawing assembly 1202, all thermal shields 2006 and 2008 are removed, thereby producing a shieldless FRU 3902. This second FRU strategy can require a second required ceiling height

$${H}_{2} = {h}_{0} + {h}_{1 B} + {h}_{2} + {h}_{3} , \qquad ( 2 )$$

where h_{1B} is a distance from the top of frames 1302 to the top of extracted FRU 3902. H₂ is somewhat less than H₁ because FRU 3902 is devoid of shields, and thus h_{1B} is less than h_{1A}. For example, a typical value can be h_{1B}≈1.4 m, whence

$${H}_{2} \approx 2.3 + 1.4 + 1.0 + 1.0 = 5.7 m . \qquad ( 2 A )$$

Unfortunately, H₂ is still significantly larger than the typical data-center ceiling height H*≈4.3 m. Consequently, the second FRU strategy illustrated on FIG. 39 is not viable for typical data centers.

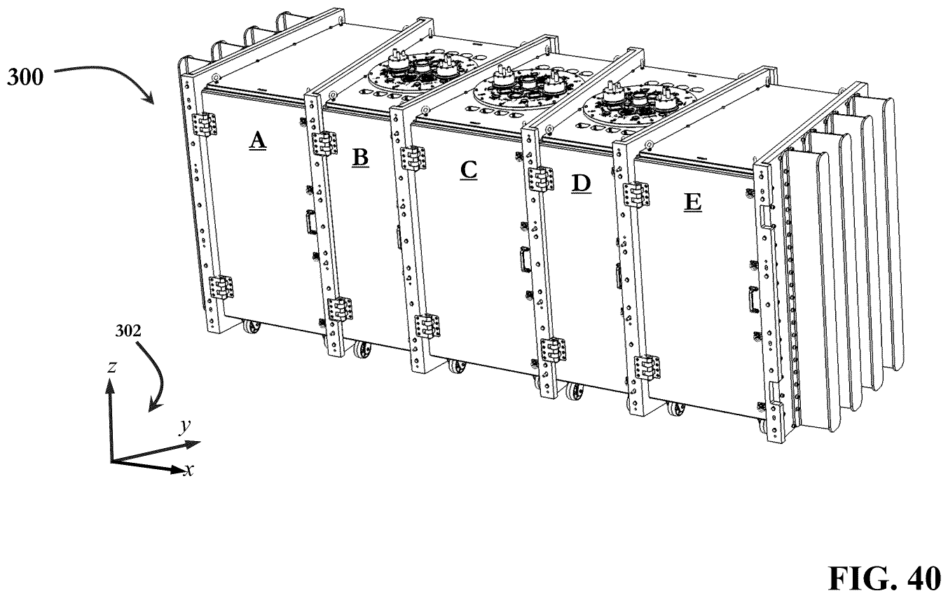

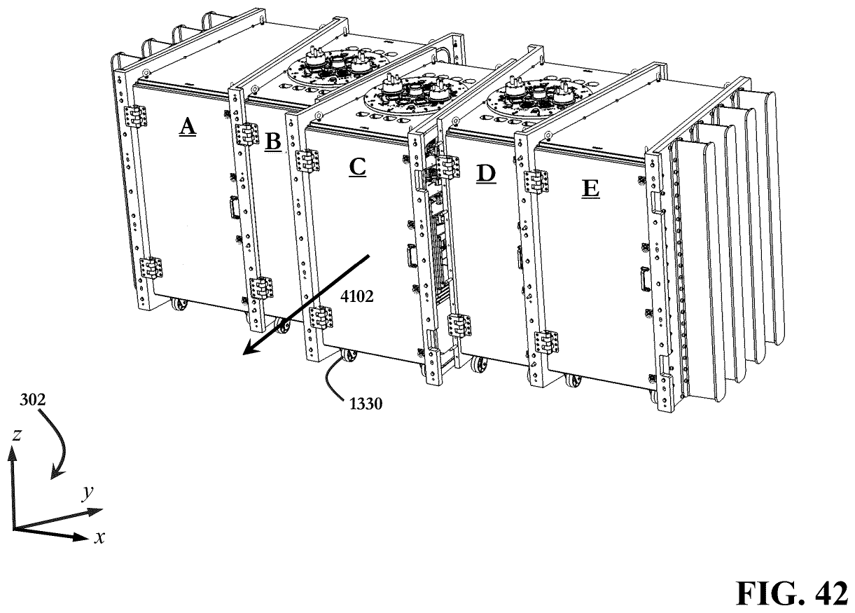

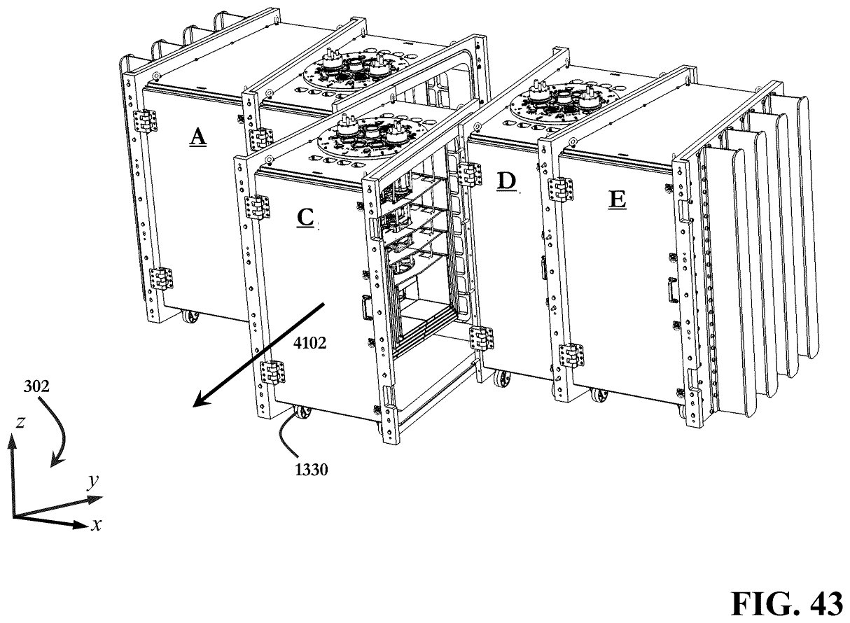

To solve this problem, embodiment 300 comprises a third FRU strategy, illustrated by FIGS. 40-49, in which the trapezoidal shape of unit cells {A B C D E} (previously mentioned in connection with FIG. 4 and FIG. 15) is used to allow an entire unit cell, including the frame assembly 704, to be extracted horizontally from embodiment 300, thereby eliminating the need to extract a FRU vertically through the skylight plate. This third strategy produces a third required ceiling height H₃ that is considerably less than H₁ or H₂, because

$${H}_{3} = {h}_{0} + {h}_{2} . \qquad ( 3 )$$

That is, in contrast to equations (1) or (2) above, the right-hand side of (3) has no term corresponding to h_{1A} or h_{1B} because horizontal FRU extraction used in the third FRU strategy requires no additional FRU-extraction height. Moreover, the right-hand side of (3) has no term corresponding to h₃ because no lifting equipment is required by the third FRU strategy. Consequently, using previously assumed typical values, a typical ceiling height H₃ for the third FRU strategy is

$${H}_{3} \approx 2.3 + 1.0 = 3.3 m , \qquad ( 3 A )$$

which is considerably less than typical data-center ceiling height H*≈4.3 m. That is, unlike the first and second FRU strategies, the third FRU strategy is viable for typical data centers.

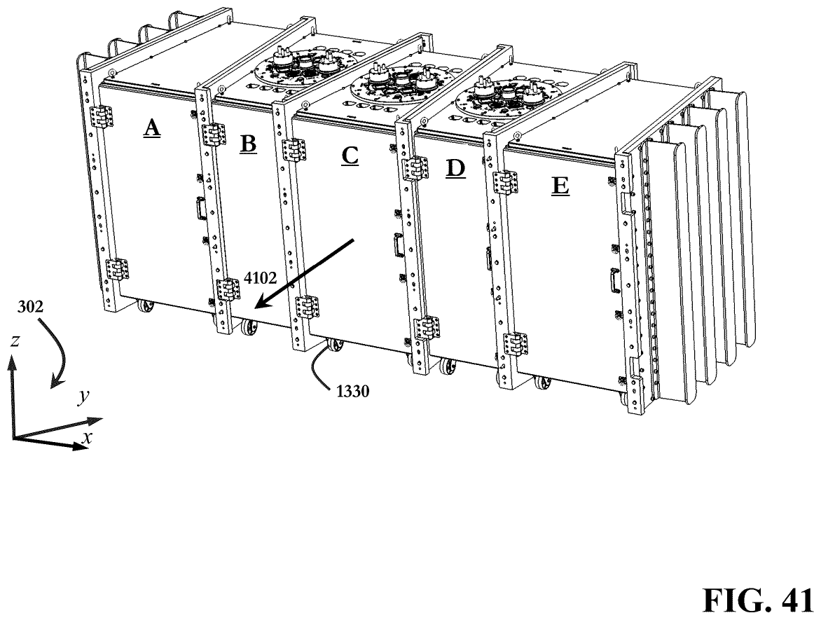

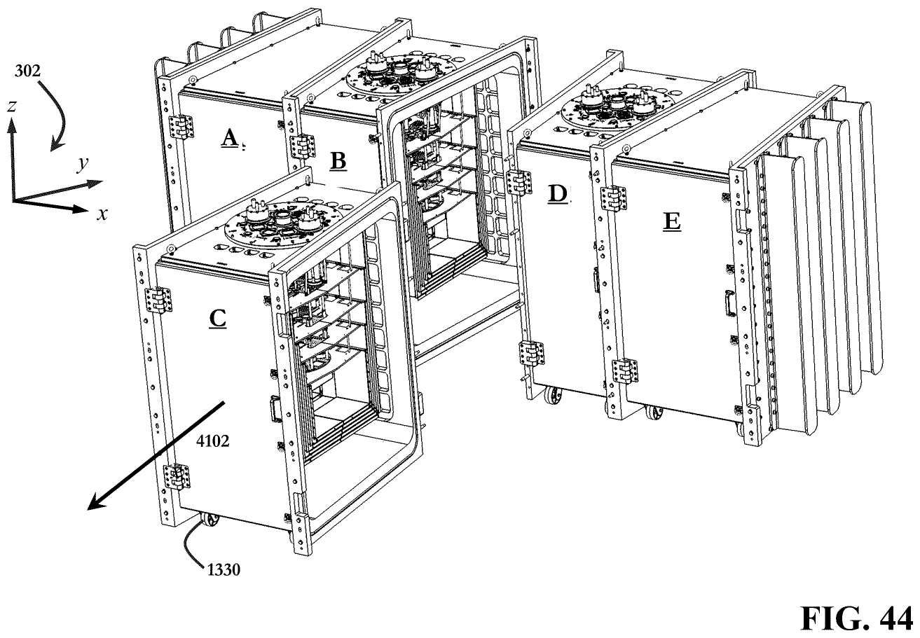

FIGS. 40-44 illustrate embodiment 300 at various stages in an extraction process in which unit cell C is removed preparatory to replacement. FIG. 40 illustrates a fully assembled configuration of embodiment 300; FIGS. 41 through 44 illustrate, respectively, a first, a second, a third, and a fourth extraction position of cell C. Extraction can be achieved by application of an extraction force 4102, a force that can be modest due to a low coefficient of rolling resistance Cᵣᵣ of mechanical casters 1330. Typically, for high-quality mechanical casters, Cᵣᵣ=0.02. If an even lower coefficient is desirable, well-known air casters, typically having Cᵣᵣ=0.002, can be used to assist the mechanical casters. In the fourth extraction position of FIG. 44, cell C is fully removed from the remainder of the array {A B D E}; cell C may be transported thence to a remote location for servicing, and a replacement cell C may undergo an insertion process that reverses the sequence illustrated by FIGS. 40-44, with force 4102 reversed.

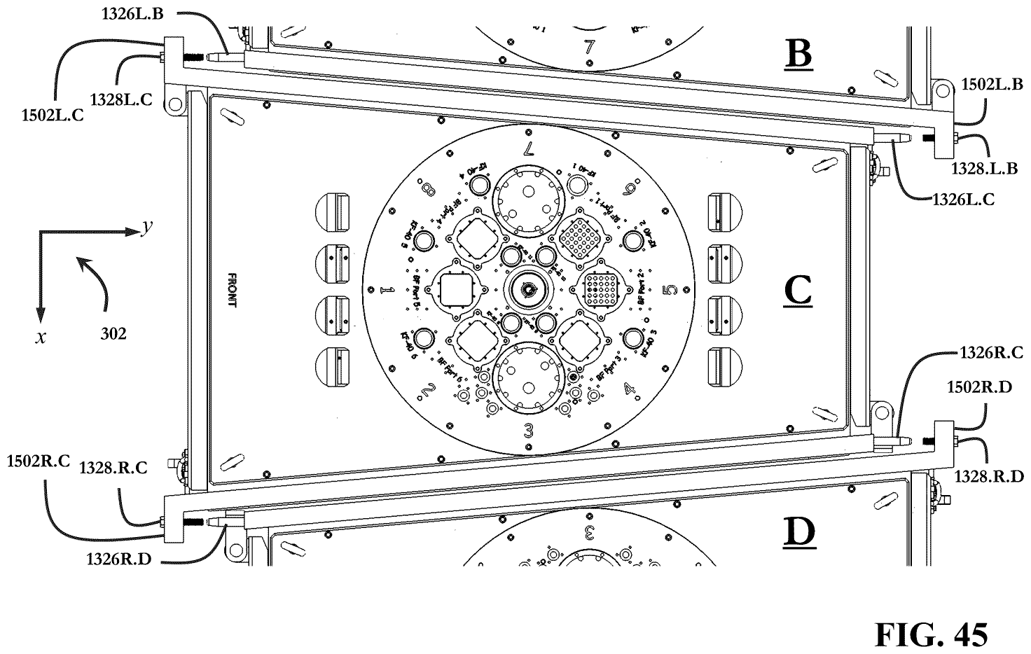

FIGS. 45-51 illustrate further details of the extraction and removal processes just described. In these figures, it is useful to add a suffix “.B”, “.C”, or “.D” to previously defined reference numerals to specify which unit cell (B, C, or D) is being referenced. For example, numeral 1502 was previously defined as the left projecting flange of frame 1302; in FIG. 45, “1502L.B” means “the left projecting flange of cell B's frame 1302”, “1502L.C means “the left projecting flange of cell C's frame 1302”, “1502R.C” means “the right projecting flange of cell C's frame 1302, and “1502R.D” means “the right projecting flange of cell D's frame 1302”.

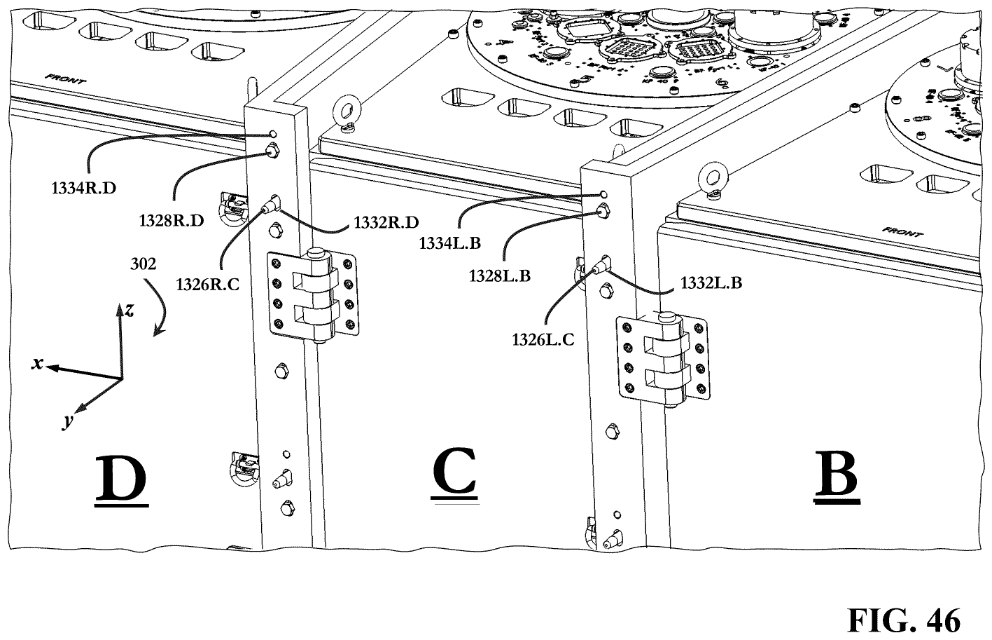

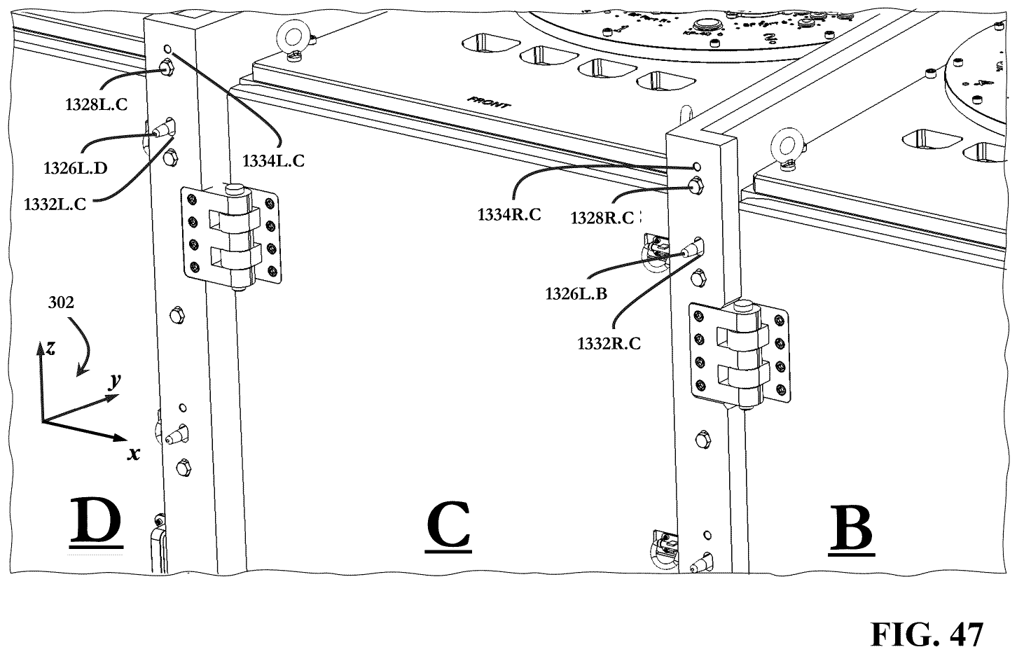

FIG. 45 is a top view corresponding to the first extraction position (FIG. 41). In contrast, FIG. 46 and FIG. 47 illustrate, respectively, rear and front perspective views that correspond to the fully assembled configuration (FIG. 40), in which four pluralities of guide pins, two at the front of cell C and two at the rear, can be fully engaged in four pluralities of guide-pin clearance holes 1332. At the rear of cell C (illustrated in FIG. 46), cell C's left guide pins 1326L.C can be engaged in cell B's left clearance holes 1332L.B, and cell C's right guide pins 1326R.C can be engaged in cell D's right clearance holes 1332R.D. At the front of cell C (illustrated in FIG. 47), cell B's right guide pins 1326L.B can be engaged in cell C's right clearance holes 1332R.C, and cell D's left guide pins 1326L.D can be engaged in cell C's left clearance holes 1332L.C.

Still referring to the fully assembled configuration of FIGS. 46-47, four pluralities of draw screws 1328 can be tightened into four pluralities of draw-screw tapped holes 1406. At the rear of embodiment 300 (illustrated in FIG. 46), cell B's left draw screws 1328L.B can be tightened into cell C's left tapped holes 1406L.C, and cell D's right draw screws 1328R.D can be tightened into cell C's right tapped holes 1406R.C. At the front of embodiment 300 (illustrated in FIG. 47), cell C's left draw screws 1328L.C can be tightened into cell B's left tapped holes 1406L.B, and cell C's right draw screws 1328R.C can be tightened into cell D's right tapped holes 1406R.D. As explained later, draw screws 1328 can be the means by which frame O-rings 702 are compressed to form the vacuum seal between frames 704.

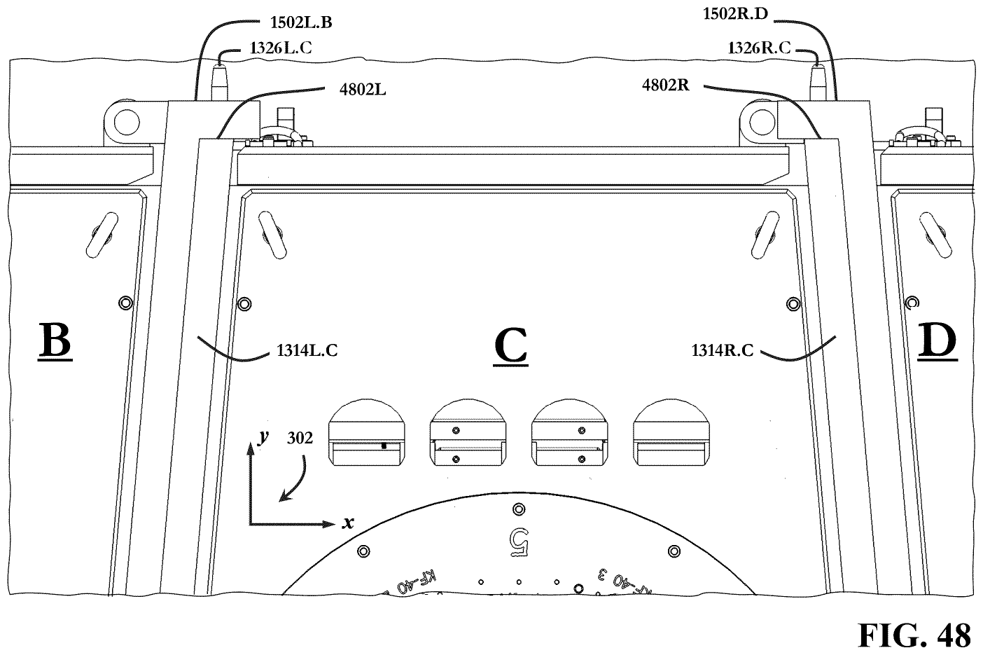

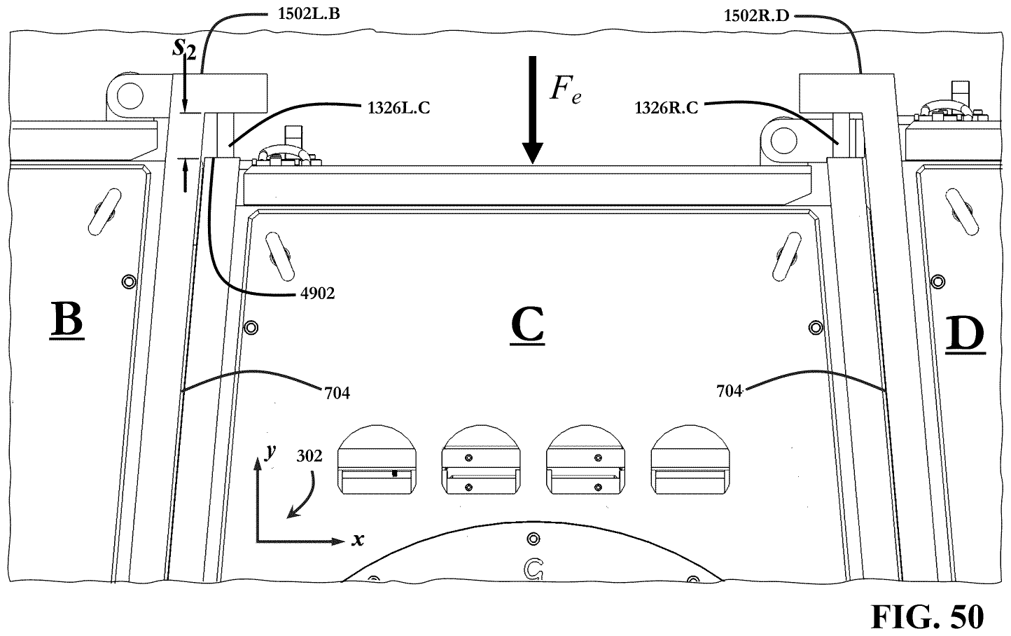

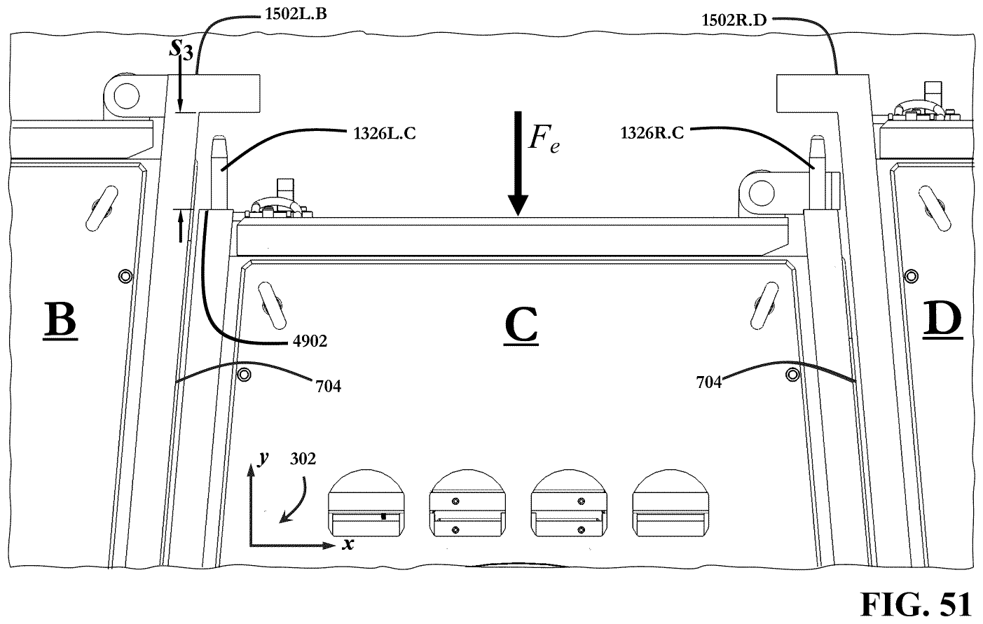

FIGS. 48-51 illustrate top views for a critical, initial portion of the extraction process during which frame O-rings 702 transition from their fully compressed state (FIG. 48) to their uncompressed state (FIGS. 50 and 51). FIGS. 48-51 focus on the rear of cell C and its abutment with neighboring cells B and D. In these four figures, all draw screws that bind cell C to cells B and D, including 1328L.C, 1328R.C, 1328L.B and 1328R.D, have been removed preparatory to the extraction process. FIG. 48 illustrates the initial, fully assembled position in which cell C's left wall 1314L.C can abut cell B's left projecting flange 1502L.B at an abutment 4802L, and likewise, cell C's right wall 1314R.C can abut cell D's right projecting flange 1502R.D at an abutment 4802R.

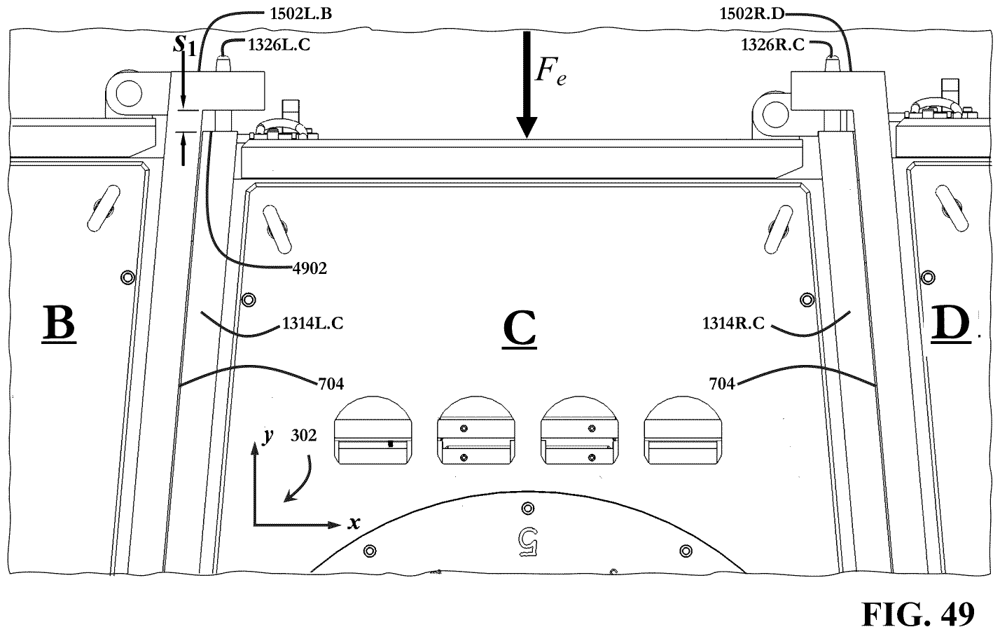

As illustrated In FIGS. 49-51, an extraction force Fₑ can be applied to cell C, causing it to translate in the −y direction, a translation that can be facilitated by mechanical casters 1330 that have a low coefficient of rolling resistance Cᵣᵣ (typically Cᵣᵣ≈0.02 for mechanical casters; Cᵣᵣ≈0.002 for air casters), as previously explained, thereby allowing Fₑ to be relatively small. If necessary to force initial separation of cell C from cells B and D, jack screws (not shown) may be threaded into holes 1334R.D and 1334L.B shown on FIG. 46, and into holes 1334L.C and 1334R.C illustrated on FIG. 47, and these screws may be tightened against jack-screw bearing areas 1408L and 1408R illustrated on FIG. 14B, thereby to force separation of cell C's frame 704 from the neighboring frames.

During the extraction process, progress can be measured by a separation distance s between projecting flange 1502L.B of cell B and a rear surface 4902 of left wall 1314L.C of cell C's frame 704. Values of s in FIGS. 48-51 are 0, s₁, s₂, and s₃, respectively, where 0<s₁<s₂<s₃. When s=0 (FIG. 48), frame O-rings 704 are fully compressed; when s=s₁ (FIG. 48), frame O-rings 702 are partially compressed; and when s≥s₂ (FIG. 48 and FIG. 49), frame O-rings 704 are completely uncompressed. Consequently, for s≥s₂, which is the vast majority of the extraction process, cell C is completely free of its neighbors B and D. This is a consequence of the trapezoidal shape of frames 704, in which walls 1314L.C and 1314R.C subtend the angle 2θ, as previously illustrated on FIG. 15. The trapezoidal shape (θ>0) thus enables the extraction process. This may be appreciated by considering the alternative of rectangular frames (θ=0), for which the extraction process would be virtually impossible, because cell C would be tightly bound to cells B and D by frictional force throughout the entire process. This would not only require a large value of F_{E} throughout the process, but would also likely damage the O-rings 702. Thus, for modular, scalable cryogenic systems such as quantum computers exemplified by embodiment 300, the trapezoidal shape of frames 704 solves an important problem: it enables modular repair at the unit-cell level without requiring a tall ceiling, as previously explained in connection with FIGS. 38-44.

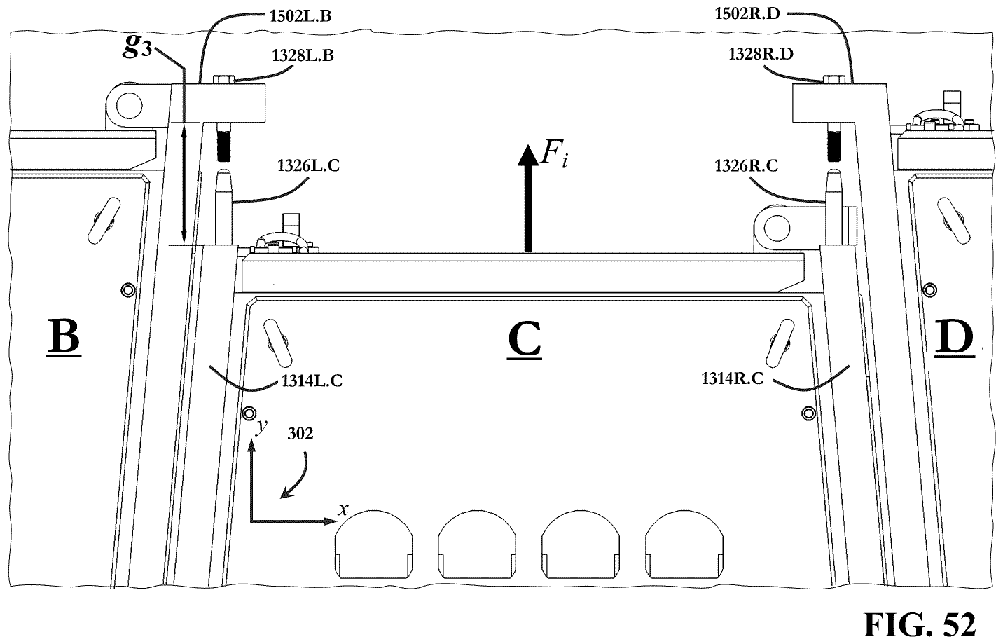

FIGS. 52-55 illustrate the insertion process of a new instance of cell C. Such an insertion process can occur either when the several unit cells of embodiment 300 are first assembled, or during a repair action, when a new instance of cell C is inserted to replace the defective cell C that has been extracted as just described.

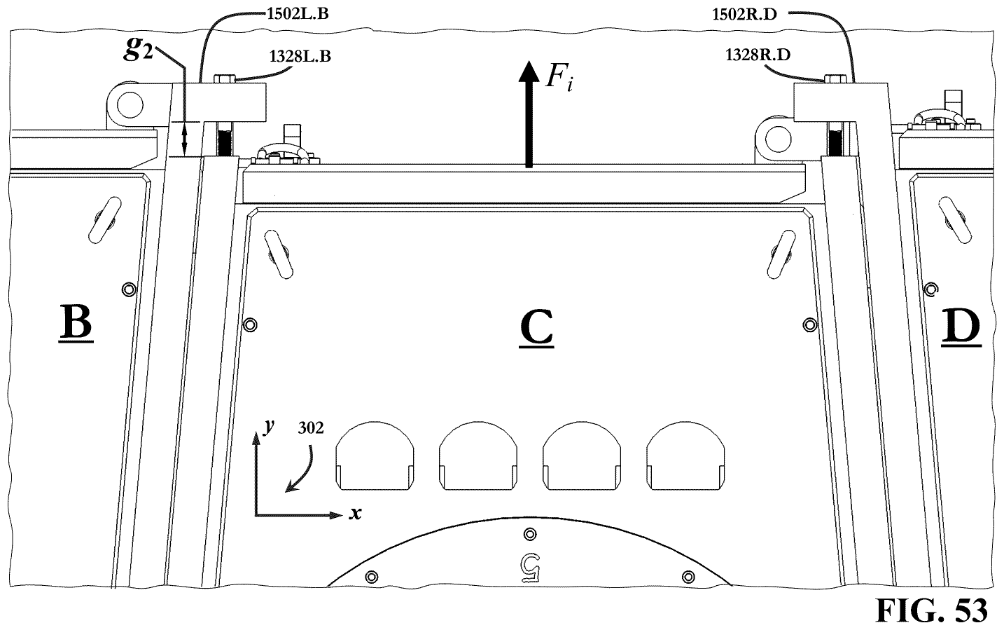

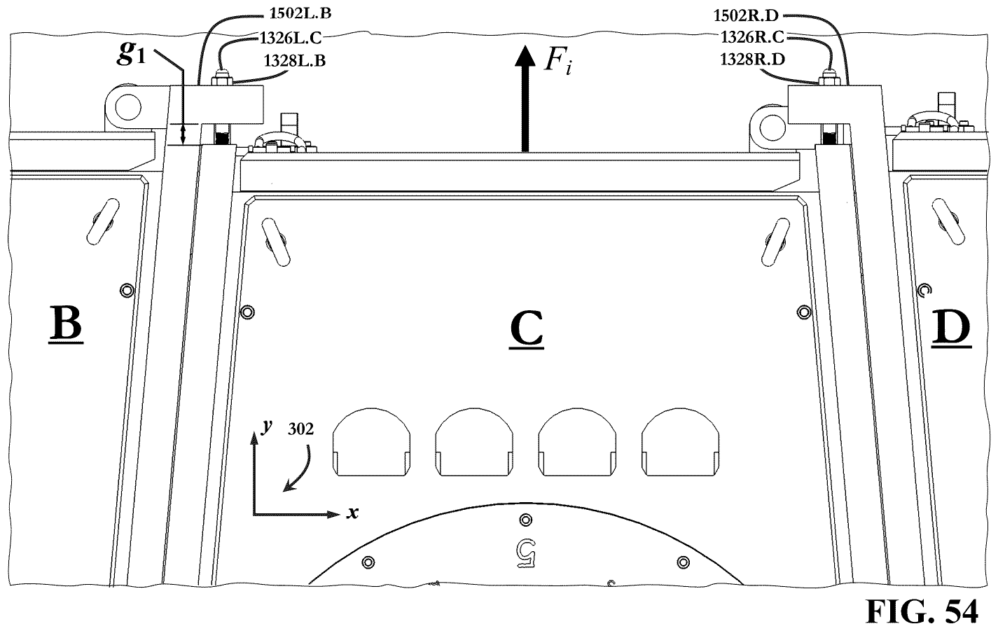

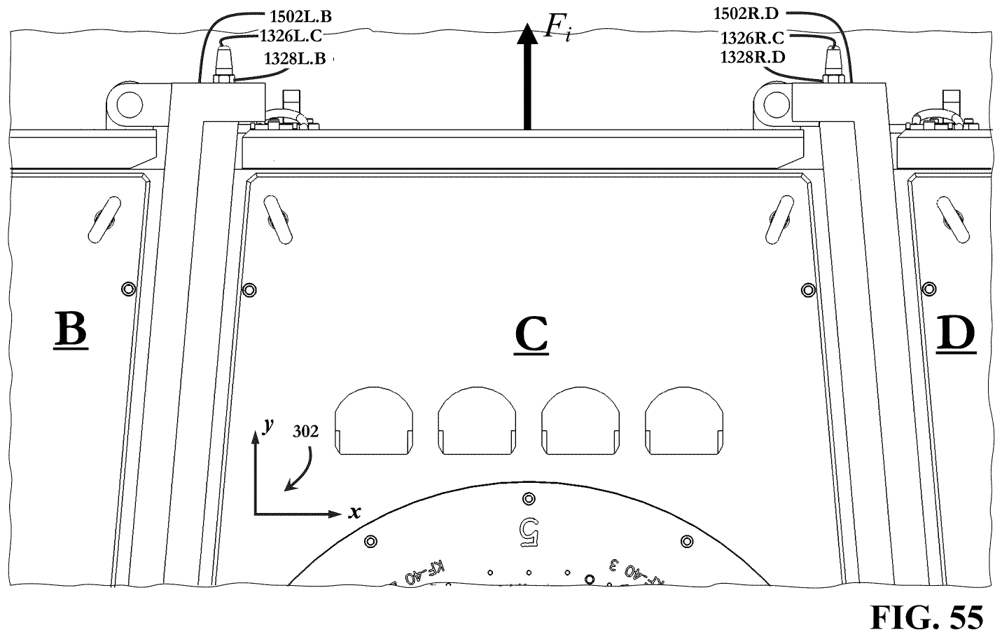

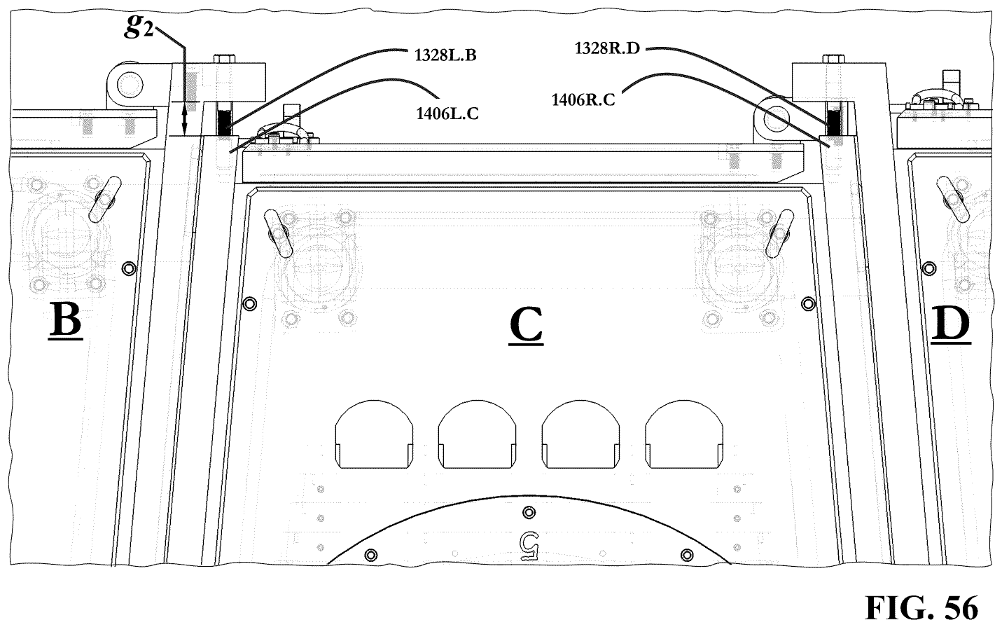

In FIGS. 52-55, insertion force Fi is applied to cell C, causing it to translate in the +y direction, a translation that can be facilitated by casters as previously described for the extraction process. During the insertion process, progress can be measured by a separation distance g between projecting flange 1502L.B of cell B and rear surface 4902 of left wall 1314L.C of cell C's frame 704. Values of g in FIGS. 52-55 are g₃, g₂, g₁, and 0, respectively, where 0<g₁<g₂<g₃. When g≥g₂, frame O-rings 702 are uncompressed; when g=g₁ (FIG. 54), frame O-rings 702 are partially compressed; when g=g₁ (FIG. 54), frame O-rings 704 are partially compressed, and when g=0 (FIG. 55), frame O-rings 702 are fully compressed. Consequently, for g≥g₂, which is most of the insertion process, cell C is completely free of its neighbors B and D. However, during a final O-ring-compressing portion of the insertion process, for which g<g₂, considerable force can be required compress O-rings 702. This force can be supplied by draw screws 1328L.B and 1328R.D illustrated on FIGS. 52-55, and previously illustrated in FIG. 46. As illustrated in FIG. 56, which is a transparent version of FIG. 53, draw screws 1328L.B and 1328R.D engage threaded holes 1406L.C and 1406R.C, respectively, prior to onset of the final, O-ring-compressing portion of the insertion process, so that the drawing force of screws 1328L.B and 1328R.D is available throughout.

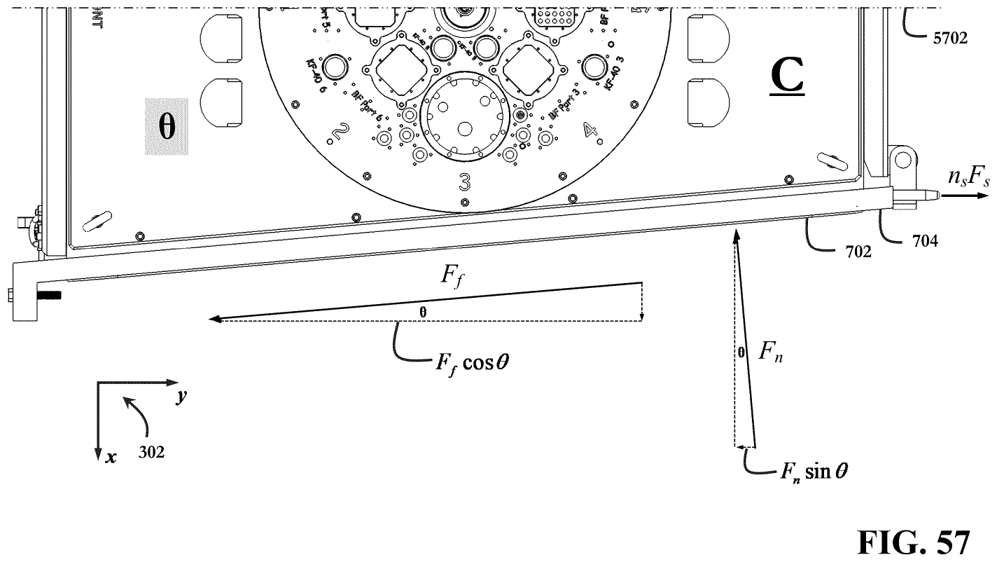

For the purpose of analyzing how large a force the draw screws must provide to draw cell C toward +y over the range 0<g<g₂, FIG. 57 illustrates a top-view, free-body diagram of the forces on cell C during the O-ring-compressing portion of the insertion process. Because frame 704 is substantially symmetric about a center plane 5702, it suffices to consider only the +x half of cell C, which is illustrated in FIG. 57. Referring to this figure, define
Fₛ≡Force exerted by one of the draw screws 1328
nₛ≡Number of draw screws 1328R.C
≡Number of draw screws 1328L.C
Fₙ≡Normal force required to compress O-ring 702
F_{f}≡Frictional force opposing motion of cell C in the +y direction.

Also recall, as illustrated on FIG. 57, θ≡Half-angle of the trapezoidal shape of frame 704.

Decomposing forces Fₙ and F_{f} into Cartesian components, and considering only the y-directed components of the forces, it follows by inspection of FIG. 57 that, for the draw-screw forces Fₛ to overcome the normal and frictional forces Fₙ and F_{f}, the following relationship must hold:

$${n}_{s} {F}_{s} \geq {F}_{n} sin θ + {F}_{f} cos θ . \qquad ( 4 )$$

That is, each draw screw must be able to provide an axial force Fₛ at least as large as

$${F}_{s} = ( {F}_{n} sin θ + {F}_{f} cos θ ) / {n}_{s} . \qquad ( 5 )$$

### Define

λₙ≡Required normal compression force per unit length of O-ring 702
λ_{f}≡Frictional force per unit length of O-ring 702 sliding on frame 704
L≡O-ring length

Then equation (5) may be written as

$${F}_{s} = L ( {λ}_{n} sin θ + {λ}_{f} cos θ ) / {n}_{s} . \qquad ( 6 )$$

For example, typical O-rings can have Shore A durometer 70, a typical O-ring compression can be 20% of its diameter, and a typical O-ring diameter for this application can be on the order of 10 mm. Under these conditions, typical values of λₙ and λ_{f} can be λₙ≈7000 [N/m] and λ_{f}≈1000 [N/m]. Typical O-ring length for applications of interest can on the order of L≈7.5 [m], a typical value of the trapezoidal half angle can be θ=5°, and a typical number of draw screws can be nₛ=9. Under these conditions,

$$\begin{matrix}{F}_{s} = ( 7. 5 [ m ] ) \{ ( 7000 [ N / m ] ) ( sin 5 ° ) + ( 1000 [ N / m ] ) ( cos 5 ° ) \} / 9 \\ = ( 7.5 [ m ] ) \{ 610 [ N / m ] + 996 [ N / m ] \} / 9 \\ = 1338 [ N ] .\end{matrix} \qquad ( 7 )$$

Draw screws 1328 for this application can be, for example, M16, each of which can supply (for strength class 8.8) an axial force of 100,000 [N], which is 75 times more than that required by the example given by equation (7). Consequently, draw screws 1328 can easily supply the force needed for compression of O-rings 702.

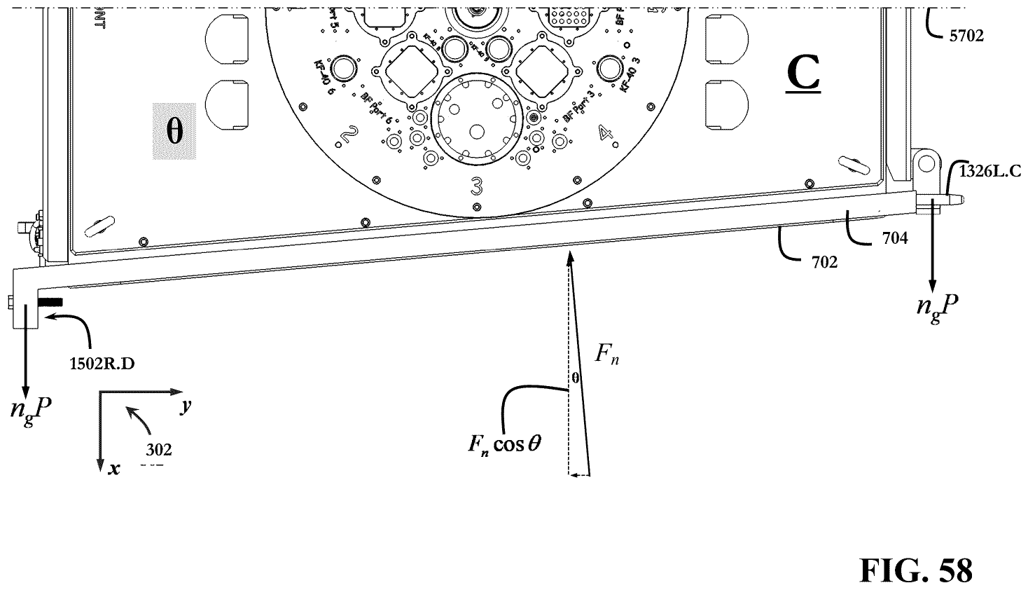

An analysis of x-directed forces is illustrated in FIG. 58. In most cases, a unit cell such as C experiences balanced x-directed forces: its −x neighbor B pushes it toward +x, while its +x neighbor D pushes with equal force toward −x. However, each end cell A and E, having only one neighbor, experiences unbalanced forces. Moreover, after an extraction process, cells that abutted the extracted cell likewise experience unbalanced forces until the missing cell is replaced using the insertion process just described. Consequently, an analysis of such unbalanced forces is warranted.

Referring to FIG. 58, define
n_{g}≡Number of guide pins 1326L.C≡Number of guide pins 1326R.D
P≡x-directed force on each guide pin

Guide pins 1326 must oppose the x-directed component of O-ring force Fₙ sin θ. The number of pins that oppose this force is 2n_{g}, including n_{g} pins 1326L.C and n_{g} pins 1326R.D. Thus,

$$2 {n}_{g} P = {F}_{n} cos θ , \qquad ( 8 )$$

whence

$$P = ( {F}_{n} cos θ ) / 2 {n}_{g} = ( {λ}_{n} L cos θ ) / 2 {n}_{g} , \qquad ( 9 )$$

where the latter equality uses the definitions of λₙ and L given previously. Substituting previously given typical values of the parameters, the force exerted on each guide pin can be

$$P = ( 7000 [ N / m ] ) ( 7.5 [ m ] ) ( cos 5 ° ) / ( 2 ) ( 9 ) = 2905 [ N ] \qquad ( 10 )$$

A typical guide-pin diameter for this application can be 20 mm, for which the lateral force given by (10) is quite modest. Consequently, the guide pins can easily handle the lateral forces associated with O-ring compression.

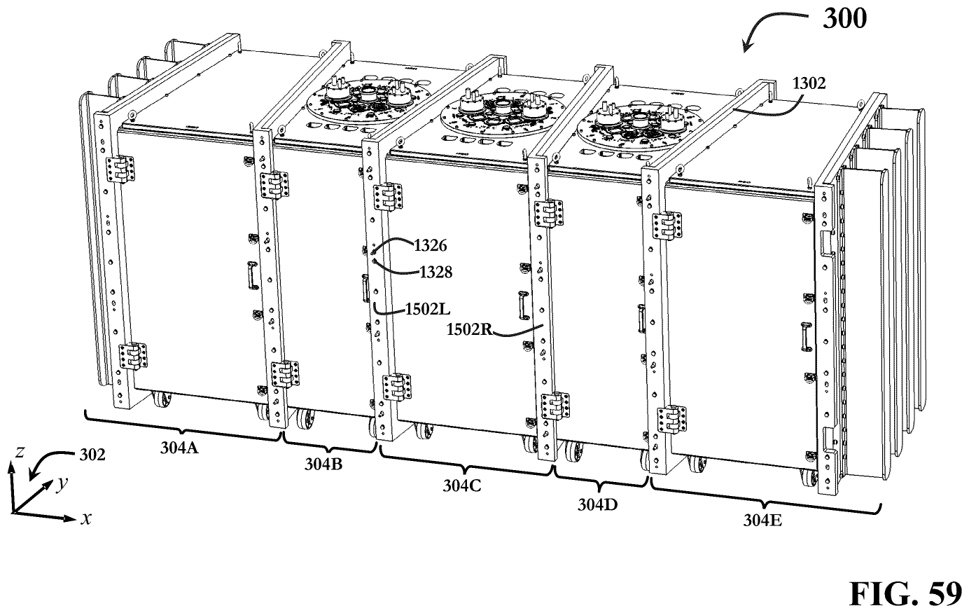

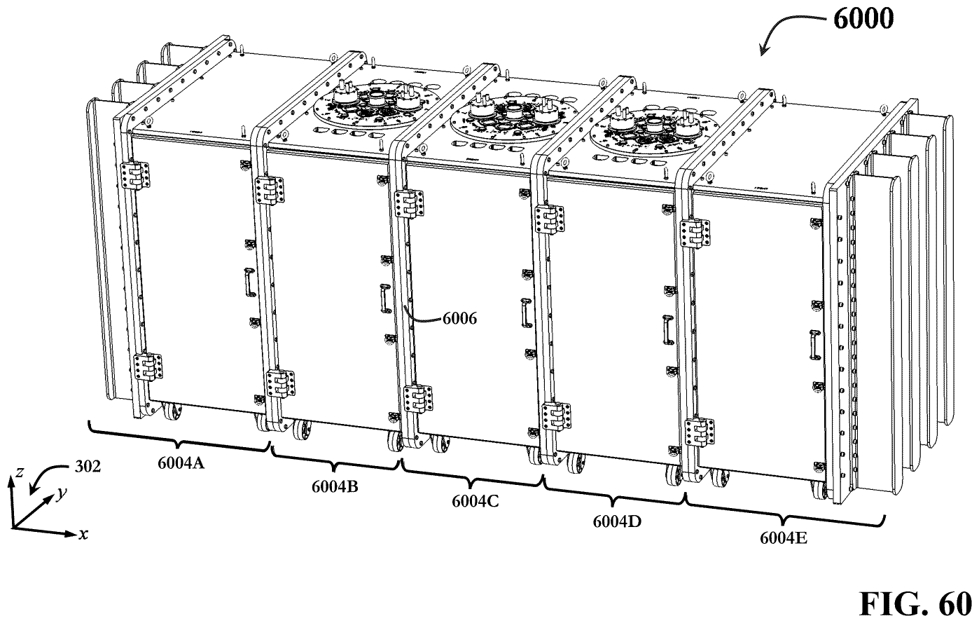

A special-case embodiment 6000 having θ=0 is illustrated in FIG. 60; for convenient comparison, it is juxtaposed to embodiment 300 in FIG. 59. As illustrated on FIG. 60, because θ=0, embodiment 6000 comprises a plurality of unit-cells {6004A, 6002B, 6004C, 6004D, 6004E}, each of which has a rectangular planform shape, as opposed to unit cells {304A, 304B, 304C, 304D, 304E} of embodiment 300, each of which has a trapezoidal planform shape. Rectangular cells 6004 lack the projecting flanges 1502, guide pins 1326, and draw screws 1328 previously described for trapezoidal cells 304. Rather, each rectangular cell 6004 can comprise a plurality of conventional flange bolts 6006, and embodiment 6000 can be assembled conventionally in a left-to-right order (6000A, then 6000B, then 6000C, then 6000D, then 6000E), or in a right-to-left order (vice-versa), with abutment of each subsequent cell occurring by translation thereof in the x direction, and subsequent bolting thereof to its abutted neighbor using flange bolts 6006. In contrast, assembly of embodiment 300 occurs by the insertion process previously explained, with abutment of each inserted cell occurring by translation thereof in the y direction, and subsequent bolting thereof to its abutted neighbor or neighbors using draw screws 1328. Therefore, the advantage of trapezoidal shaped frames 304 (i.e., the ability to remove and re-insert a cell anywhere in the array by means of the extraction and insertion processes discussed in connection with FIGS. 48-51) does not apply, for all practical purposes, to rectangular frames 6002, for reasons discussed in connection with those figures. That is, once embodiment 6000 is assembled, it is very difficult to remove and replace a populated cell that has failed. Consequently, FRU removal and replacement for embodiment 6000 cannot, for all practical purposes, use the third, FRU strategy (i.e., horizontal FRU extraction) previously described in connection with equation (3). Rather, embodiment 6000 can use the first or second FRU strategy (i.e., vertical FRU extraction) previously described in connection with equations (1) and (2). However, as previously explained, vertical FRU extraction, and therefore embodiment 6000, is not amenable to conventional data centers with relatively low ceilings. Nevertheless, for buildings with high ceilings amenable to vertical FRU extraction, or for applications in which FRU removal and replacement is not a concern, embodiment 6000 can be useful.

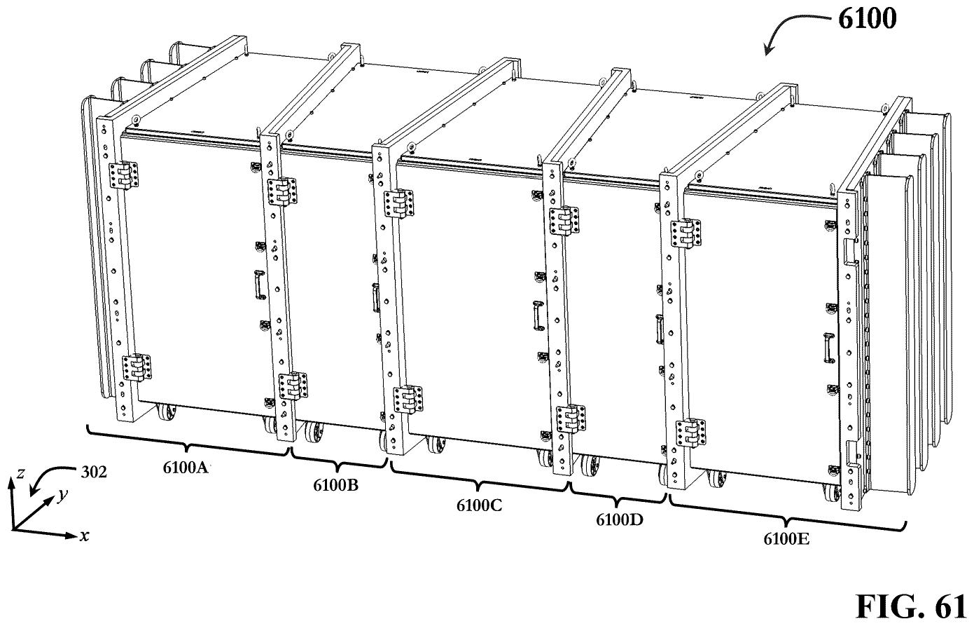

FIG. 61 illustrates a generic embodiment 6100, in which all cells (e.g., 6100A, 6100B, 6100C, 6100D, and 6100E) are unpopulated, like cells 300A and 300E of embodiment 300. Embodiment 6100 may be applicable to applications other than quantum computing that require equipment other than dilution refrigerators, yet may still benefit from the trapezoidal shaped cells which allow horizontal extraction and insertion of unit cells.

Embodiments of the present invention may be a system, a method, and/or an apparatus at any possible technical detail level of integration. What has been described above includes mere examples of systems, methods, and apparatus. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings, such terms are intended to be inclusive in a manner similar to the term “comprising” as “comprising” is interpreted when employed as a transitional word in a claim.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain example embodiments have been described, these embodiments have been presented by way of example only, and are not intended to limit the scope the disclosures herein. Thus, nothing in the foregoing description is intended to imply that any particular feature, characteristic, step, module, or block is necessary or indispensable. Indeed, the novel methods and systems described herein may be embodied in a variety of other forms; furthermore, various omissions, substitutions and changes in the form of the methods and systems described herein may be made without departing from the spirit of the disclosures herein. The accompanying claims and their equivalents are intended to cover such forms or modifications as would fall within the scope and spirit of certain of the disclosures herein.

What is claimed is:

1. A cryogenic system comprising:
a plurality of trapezoidal unit cells joined together, wherein each trapezoidal unit cell comprises:
a frame, wherein frames from adjacent trapezoidal unit cells are connected in a vacuum-tight manner at abutting surfaces of the adjacent trapezoidal unit cells.

2. The system of claim 1, wherein each frame comprises an O-ring placed in an O-ring groove cut into a left face of the frame or a right face of the frame, and wherein the frames from the adjacent trapezoidal unit cells are connected in a vacuum-tight manner by compressing the O-ring between the abutting surfaces.

3. The system of claim 1, wherein a trapezoidal unit cell is capable of being horizontally removed from or inserted into the plurality of joined trapezoidal unit cells.

4. The system of claim 1, further comprising at each end of the plurality of trapezoidal unit cells an end frame, wherein the plurality of frames and end frames together form a vacuum-tight vessel.

5. The system of claim 2, wherein the plurality of trapezoidal unit cells are joined together by interleaving the trapezoidal unit cells containing an O-ring in the left face with the trapezoidal unit cells containing an O-ring in the right face.

6. The system of claim 2, further comprising on each frame of the plurality of trapezoidal unit cells:
a set of front flanges, wherein the O-ring is compressed by threaded fasteners on the set of front flanges.

7. The system of claim 6, wherein the set of front flanges are engaged by guide pins for insertion of the trapezoidal unit cell.

8. The system of claim 1, wherein the plurality of trapezoidal unit cells comprises a unit-cell-to-unit-cell pitch between 500 millimeters and 1500 millimeters.

9. A cryogenic system comprising:
a plurality of unit cells joined together, wherein each unit cell comprises:
a frame;
a plurality of nested temperature shells wherein a subset of shells are at different temperature levels;
at least one retrofitted version of a standard dilution refrigerator; and
at least one cryogenic payload located within at least one of the temperature levels, that is cooled by the at least one retrofitted version of a standard dilution refrigerator, wherein frames from adjacent unit cells are connected in a vacuum-tight manner at abutting surfaces of the adjacent unit cells, and at each temperature level, temperature shells from the adjacent unit cells are connected to form a continuous, global temperature shell.

10. The system of claim 9, wherein each frame comprises an O-ring placed in an O-ring groove cut into a left face of the frame or a right face of the frame, and wherein the frames from the adjacent unit cells are connected in a vacuum-tight manner by compressing the O-ring between the abutting surfaces.

11. The system of claim 9, wherein a unit cell is capable of being horizontally removed from or inserted into the plurality of joined unit cells.

12. The system of claim 9, further comprising at each end of the plurality of unit cells:
an end frame, wherein the plurality of frames and end frames together form a vacuum-tight vessel; and
an end cap for the global temperature shell at each end of the plurality of unit cells, wherein the global temperature shell and end caps form a substantially closed, radiation-resistant thermal enclosure.

13. The system of claim 10, wherein the plurality of unit cells are joined together by interleaving the unit cells containing an O-ring in the left face with the unit cells containing an O-ring in the right face.

14. The system of claim 9, further comprising on each frame of the plurality of unit cells:
a set of front flanges, wherein the O-ring is compressed by threaded fasteners on the set of front flanges.

15. A cryogenic system comprising:
a plurality of trapezoidal unit cells joined together, wherein each trapezoidal unit cell comprises:
a frame assembly comprising at least one door that forms a vacuum-tight seal when closed;
at least one temperature shell suspended from a set of refrigerator flanges;
at least one retrofitted version of a standard dilution refrigerator; and
at least one cryogenic payload located within the at least one temperature shell, that is cooled by the at least one retrofitted version of a standard dilution refrigerator, wherein frames from adjacent trapezoidal unit cells are connected in a vacuum-tight manner at abutting surfaces of the adjacent trapezoidal unit cells, and temperature shells from the adjacent trapezoidal unit cells are connected to form a continuous, global temperature shell.

16. The system of claim 15, wherein each frame comprises an O-ring placed in an O-ring groove cut into a left face of the frame or a right face of the frame, and wherein the frames from the adjacent trapezoidal unit cells are connected in a vacuum-tight manner by compressing the O-ring between the abutting surfaces.

17. The system of claim 15, wherein a trapezoidal unit cell is capable of being horizontally removed from or inserted into the plurality of joined trapezoidal unit cells.

18. The system of claim 15, further comprising at each end of the plurality of trapezoidal unit cells
an end frame, wherein the plurality of frames and end frames together form a vacuum-tight vessel; and
an end cap for the global temperature shell at each end of the plurality of trapezoidal unit cells, wherein the global temperature shell and end caps form a substantially closed, radiation-resistant thermal enclosure.

19. The system of claim 16, wherein the plurality of trapezoidal unit cells are joined together by interleaving the trapezoidal unit cells based on position of the O-ring, such that wide ends of a trapezoidal unit cell are placed next to narrow ends of adjacent trapezoidal unit cells.

20. The system of claim 15, further comprising on each frame of the plurality of trapezoidal unit cells:
a set of front flanges, wherein the O-ring is compressed by threaded fasteners on the set of front flanges.
